(19) United States
(12) Patent Application Publication
(10) Pub. No.: US 2024/0421119 A1
(43) Pub. Date: Dec. 19, 2024

(54) FLEXIBLE UNDER-BUMP METALLIZATION (UBM) SIZES AND PATTERNING, AND RELATED INTEGRATED CIRCUIT (IC) PACKAGES AND FABRICATION METHODS

(71) Applicant: QUALCOMM Incorporated, San Diego, CA (US)

(72) Inventors: Yangyang Sun, San Diego, CA (US); Yue Li, San Diego, CA (US); Lily Zhao, San Diego, CA (US); Piyush Gupta, San Diego, CA (US); Xuefeng Zhang, San Diego, CA (US)

(21) Appl. No.: 18/336,331

(22) Filed: Jun. 16, 2023

(51) Int. Cl. H01L 23/00

(52) U.S. Cl. CPC H01L 24/81; H01L 24/04; H01L 24/16; H01L 24/73; H01L 2224/0401; H01L 2224/16245; H01L 2224/73204

(57) ABSTRACT

Flexible under-bump metallization sizes and patterning, and related integrated circuit packages and fabrication methods are disclosed. First under-bump metallizations (UBMs) of a first, larger size and pitch are provided in the die and coupled to corresponding metal interconnects in the package substrate. One or more second UBMs of a second, reduced size UBMs can also be located in the core area of the die. This provides greater flexibility in the design and layout of the die, because different circuits within the die (e.g., I/O related circuits) may only require coupling to smaller size UBMs for performance requirements and thus can be more flexibility located in the die. Also, to further reduce pitch of the second, smaller size UBMs, one or more of the second, smaller size UBMs can be formed as oblong-shaped UBMs, which can still maintain a minimum separation based on metal interconnect pitch limitations in the package substrate.

### BACKGROUND

### I. Field of the Disclosure

The field of the disclosure relates to integrated circuit (IC) packages that include one or more semiconductor dies (“dies”) attached to a package substrate, and more particularly to interconnect bump designs in the IC package for electrically coupling a die(s) to the package substrate.

### II. Background

Integrated circuits (ICs) are the cornerstone of electronic devices. ICs are typically packaged in an IC package, also called a “semiconductor package” or “chip package.” The IC packages can be included in hand-held, battery-powered electronic devices, for example, where reduced package size and reduced power consumption is particularly important. A conventional IC package (e.g., a flip-chip IC package) includes a package substrate and one or more semiconductor dies (“dies”) and other electronic modules mounted to the package substrate to provide electrical connectivity to the die(s). The die is electrically coupled to the package substrate through metal die interconnects such as in the form of solder bumps or copper pillars, also known as “die interconnects,” “die interconnect bumps,” or just “die bumps.” Metal traces or metal lines in metallization layers in the package substrate are coupled to the die bumps to route electrical signals external to the IC package as well as to other coupled dies in the IC package. Some metal traces in the package substrate are dedicated for delivering power as part of a power distribution network (PDN) in an IC package, while other metal traces in the package substrate are dedicated for carrying signals, such as input/output (I/O) signals.

The pitch of the die bumps coupling the die(s) to the package substrate influences the size of the die(s). For example, a die that has a larger quantity of die bumps requires a larger die area than a die that has a smaller quantity of die bumps for a given die bump pitch. Thus, it may be desired to reduce the die bump pitch to conserve die area and thus conserve the overall IC package size. However, reducing die bump pitch can be challenging in IC package designs. Some IC packages, such as those involving radio frequency (RF) technology, may have a larger number of bump keep-out-zones (KOZs). Also, reducing die bump pitch in an IC package is sometimes not possible given package fabrication process limitations of the package substrate. Even when realization of reduced die bump pitch in a die in an IC package is possible within fabrication process limitations, reduced die bump pitch can cause a reduction in yield as well as higher assembly costs.

### SUMMARY OF THE DISCLOSURE

Aspects disclosed in the detailed description include flexible under-bump metallization (UBM) sizes and patterning, and related integrated circuit (IC) packages and fabrication methods. In exemplary aspects, a semiconductor die (“die”) includes an interconnect structure that includes a plurality of UBMs to facilitate the formation of interconnect bumps (e.g., solder bumps, metal bumps) to provide die interconnects. A UBM is a layer of metal that formed in contact with metal pads in a semiconductor die to provide an electrical and mechanical connection of the die and a substrate, such as a package substrate. The raised interconnect bumps of the die interconnects can be coupled to corresponding metal interconnects in a package substrate, such as through a bump-on-pad process, as part of an IC package to provide an electrical interconnect interface between the die and the package substrate for signal routing. Thus, the UBMs in the die and corresponding metal interconnects in the package substrate are formed according to a bump pattern that aligns the raised interconnect bumps and the metal interconnects in the package substrate to be coupled together in the IC package.

It may be desired to provide mixed UBM sizes for routing of different types of signals to minimize die area and thus the size of the IC package and/or increase die interconnect density. In this regard, first UBMs of a first, larger size and pitch can be provided in the die and coupled to corresponding metal interconnects in the package substrate (e.g., in a solder-on-pad or bond-on-pad connection) to route signals (e.g., power signals with reduced resistance and thus increased power performance). Second UBMs of a second, smaller size (smaller that the first size of the first UBMs) and pitch can be provided in the die and coupled to metal interconnects in the package substrate (e.g., in a bond-on-trace connection) for routing signals (e.g., input/output (I/O) signals) outside of the core area of the die. UBM size refers to a two-dimensional area or other dimension of a UBM in the plane of the surface of the die in which the UBMs are coupled. For example, UBM size can be defined in terms of its overall area or other dimension such as diameter, length, and/or width, in the plane of the surface of the die in which the UBMs are coupled. The core area of the die refers to a centralized region of the die where the UBMs and/or their die bumps are located on the surface of the die for providing die interconnects. In exemplary aspects, to provide further design flexibility for UBM patterning, one or more of the second UBMs of the second, smaller size UBMs can be located in the core area of the die. This provides greater flexibility in the design and layout of the die, because different circuits within the die (e.g., power-related circuits and I/O-related circuits) may only require coupling to smaller size UBMs for performance requirements and thus can be more flexibly located in the die. Also, one or more of the first UBMs of the first, larger size can be located in the periphery area(s) of the die. The periphery area of the die refers to a region extending from edges of the die to and surrounding a core area of the die where UBMs and/or their die bumps can also be located on the surface of the die for providing die interconnects. For example, it may be desired to provide first, larger size UBMs in the periphery area(s) of the die to reduce connection length to a coupled component on the package substrate adjacent to the die (e.g., a capacitor or inductor for power conditioning).

Also, in other exemplary aspects, to further reduce the pitch of the second, smaller size UBMs, such as to have the flexibility to further reduce die area and/or increase die interconnect density, one or more of the second, smaller size UBMs are formed as oblong-shaped UBMs. An oblong-shaped UBM is a UBM that has an elongated, first length in a first direction, and a smaller, second length less than the first length in a second direction orthogonal to the first direction. Examples of oblong-shaped UBMs are elliptical-shaped UBMs and rectangular-shaped UBMs. Providing second, smaller size UBMs as oblong-shaped UBMs can support a further reduction in UBM pitch, because a minimum distance provided between adjacent oblong-shaped UBMs that is based on the minimum pitch process limitations of the corresponding coupled metal interconnects in the package substrate can be maintained. In this manner, being able to provide second, smaller size UBMs not only in the core area of the die, but as oblong-shaped UBMs, can provide even greater flexibility in the circuit layout design of the die, and/or be used to reduce die area and/or to provide even greater die interconnect density.

In other exemplary aspects, different patterns of second, smaller-shaped UBMs that include oblong-shaped UBMs can be provided to relax process limitations on the pitch of the corresponding coupled metal interconnects in the package substrate. For example, in one aspect, one or more columns of the smaller-size UBMs can include adjacent symmetrical and oblong-shaped UBMs in an alternating pattern. In another aspect, one or more adjacent rows of the smaller-size UBMs can include adjacent symmetrical and oblong-shaped UBMs in an alternating pattern.

In additional exemplary aspects, one or more of the second, smaller size oblong-shaped UBMs can be oriented in the die such that the elongated axes of the oblong-shaped UBMs are oriented in a direction towards the center area of the die. In this manner, when a stress force is applied to the raised interconnect bumps of the die interconnects with such oriented UBMs by their coupling to the package substrate, such as due to warpage that may be a result of a mismatch in coefficient of thermal expansion (CTE) between the die interconnects and the package substrate, at least some of the stress is applied in the elongated direction of the second, smaller size oblong-shaped UBMs to be applied to a greater area of the second, smaller size oblong-shaped UBMs. This can better maintain the integrity of the coupling of the second, smaller size oblong-shaped UBMs to the package substrate in the presence of warpage or other forces to better maintain the integrity of the IC package.

In one exemplary aspect, a semiconductor die (die) is provided. The die has a core area and a periphery area surrounding the core area. The die comprises a plurality UBMs comprising a plurality of first UBMs each having a first size and a first pitch, and a plurality of second UBMs each having a second size smaller than the first size, and each having a second pitch less than the first pitch. A first subset of the plurality of second UBMs is in the core area.

In another exemplary aspect, a method of fabricating an IC package is provided. The method comprises providing die comprising a core area and a periphery area surrounding the core area. The method also comprises forming a plurality of UBMs in the die, comprising forming a plurality of first UBMs each having a first size and a first pitch, and forming a plurality of second UBMs each having a second size smaller than the first size, and each having a second pitch less than the first pitch. Forming the plurality of second UBMs further comprises forming a first subset of the plurality of second UBMs in the core area of the die.

In another exemplary aspect, an IC package is provided. The IC package comprises a package substrate, comprising: a first metallization layer comprising a plurality of first metal interconnects and a plurality of second metal interconnects, and a die. The die comprises a core area and a periphery area surrounding the core area. The die also comprises a plurality of UBMs comprising a plurality of first UBMs each having a first size and a first pitch, and a plurality of second UBMs each having a second size smaller than the first size, and each having a second pitch less than the first pitch, wherein a first subset of the plurality of second UBMs is in the core area. Each first UBM of the plurality of first UBMs is coupled to a first metal interconnect of the plurality of first metal interconnects. Each second UBM of the plurality of second UBMs is coupled to a second metal interconnect of the plurality of second metal interconnects.

### BRIEF DESCRIPTION OF THE FIGURES

FIG. 1A is a cross-sectional side view of an exemplary integrated circuit (IC) package that includes a semiconductor die (“die”) with die interconnects coupled to corresponding metal interconnects in a package substrate;

FIG. 1B is a cross-sectional section of the IC package in FIG. 1A illustrating an exemplary solder-on-pad (SOP) process of coupling a raised interconnect bump of a die interconnect to a solder bump disposed in a solder resist layer opening (SRO) in a package substrate and connected to a metal interconnect in an outer metallization layer in the package substrate;

FIG. 1C is a cross-sectional section of the IC package in FIG. 1A illustrating an exemplary bond-on-pad process of coupling a raised interconnect bump of a die interconnect to a metal interconnect in a package substrate exposed from a SRO in the package substrate;

FIG. 2 is a table illustrating exemplary UBM pitches for corresponding UBM and solder resist layer opening (SRO) sizes for SOP and bond-on-pad processes;

FIG. 3 is a bottom view of an exemplary die that can be provided in an IC package, wherein the die includes under-bump metallizations (UBMs) in a UBM pattern that includes first UBMs of a first, larger size and pitch that can be located in a core area of the die, and second UBMs of a second, smaller size and pitch that are located in the periphery area(s) and core area of the die, to facilitate greater flexibility in the design and layout of the die;

FIG. 4 is a side, cross-sectional view of die interconnects and an adjacent, outer metallization layer of a package substrate in an exemplary IC package, illustrating a bond-on-pad connection for a first die interconnect having a first UBM of a first, larger size and pitch, and a bond-on-trace connection for a second die interconnect having a second UBM of a second, smaller size and pitch;

FIG. 5 is a bottom view of an exemplary die that includes UBMs in a UBM pattern to illustrate different sizes and pitches of first UBMs of a first, larger size and pitch and second, oblong-shaped UBMs of a second, smaller size and pitch;

FIG. 6A is a bottom view of another exemplary die that can be provided in an IC package, wherein the die includes UBMs in a UBM pattern that includes first UBMs of a first, larger size and pitch that can be located in periphery areas and/or the core area of the die, and second, oblong-shaped UBMs of a second, smaller size and pitch that are located in the periphery area(s) and core area of the die, to facilitate greater flexibility in the design and layout of the die;

FIG. 6B is a top view of an IC package that includes the die in FIG. 6A with its die interconnects that includes the first and second UBMs, coupled to corresponding metal interconnects in a package substrate;

FIG. 7 is a bottom view of an exemplary UBM pattern in a die that includes columns and rows of adjacent symmetrical and second, oblong-shaped UBMs in an alternating pattern;

FIG. 8 is a bottom view of another UBM pattern in a die that includes columns and rows of adjacent symmetrical and angled second, oblong-shaped UBMs in an alternating pattern;

FIG. 9 is a flowchart illustrating an exemplary process of fabricating an IC package that includes a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages and dies in FIGS. 3-8;

FIGS. 10A-10C is a flowchart illustrating another exemplary fabrication process of fabricating an IC package that includes a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages and dies in FIGS. 3-8;

FIGS. 11A-11H illustrate exemplary fabrication stages in the fabrication process in FIGS. 10A-10C;

FIG. 12 is a block diagram of an exemplary wireless communications device that includes radio frequency (RF) components provided in one or more IC packages that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages and dies in FIGS. 3-8 and 11A-11H and according to the exemplary fabrication processes in FIGS. 9 and 10A-10C; and

FIG. 13 is a block diagram of an exemplary processor-based system that can be provided in one or more IC packages that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages and dies in FIGS. 3-8 and 11A-11H and according to the exemplary fabrication processes in FIGS. 9 and 10A-10C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include flexible under-bump metallization sizes and patterning, and related integrated circuit (IC) packages and fabrication methods. In exemplary aspects, a semiconductor die (“die”) includes an interconnect structure that plurality of under-bump metallizations (UBMs) to facilitate the formation of raised interconnect bumps (e.g., solder bumps, metal bumps) to provide die interconnects. A UBM is a layer of metal that formed in contact with metal pads in a semiconductor die to provide an electrical and mechanical connection of the die and a substrate, such as a package substrate. The raised interconnect bumps of the die interconnects can be coupled to corresponding metal interconnects in a package substrate, such as through a bump-on-pad process, as part of an IC package to provide an electrical interconnect interface between the die and the package substrate for signal routing. Thus, the UBMs in the die and corresponding metal interconnects in the package substrate are formed according to a bump pattern that aligns the raised interconnect bumps and the metal interconnects in the package substrate to be coupled together in the IC package.

It may be desired to provide mixed UBM sizes for routing of different types of signals to minimize die area and thus the size of the IC package and/or increase die interconnect density. In this regard, first UBMs of a first, larger size and pitch can be provided of the die and coupled to corresponding metal interconnects in the package substrate (e.g., in a solder-on-pad or bond-on-pad connection) to route signals (e.g., power signals with reduced resistance and thus increased power performance). Second UBMs of a second, smaller size (smaller that the first size of the first UBMs) and pitch can be provided in the die and coupled to metal interconnects in the package substrate (e.g., in a bond-on-trace connection) for routing signals (e.g., input/output (I/O) signals) outside of the core area of the die. UBM size refers to a two-dimensional area or other dimension of a UBM in the plane of the surface of the die in which the UBMs are coupled. For example, UBM size can be defined in terms of its overall area or other dimension such as diameter, length, and/or width, in the plane of the surface of the die in which the UBMs are coupled. The core area of the die refers to a centralized region of the die where the UBMs and/or their die bumps are located on the surface of the die for providing die interconnects. In exemplary aspects, to provide further design flexibility for UBM patterning, one or more of the second UBMs of the second, smaller size UBMs can be located in the core area of the die. This provides greater flexibility in the design and layout of the die, because different circuits within the die (e.g., power related circuits and I/O related circuits) may only require coupling to smaller size UBMs for performance requirements and thus can be more flexibility located in the die. Also, one or more of the first UBMs of the first, larger size can be located in the periphery area(s) of the die. The periphery area of the die refers to a region extending from edges of the die to and surrounding a core area of the die where UBMs and/or their die bumps can also be located on the surface of the die for providing die interconnects. For example, it may be desired to provide first, larger size UBMs on the periphery area(s) of the die to reduce connection length to a coupled component on the package substrate adjacent to the die (e.g., a capacitor or inductor for power conditioning).

Also, in other exemplary aspects, to further reduce the pitch of the second, smaller size UBMs, such as to have the flexibility of further reduce die area and/or increase die interconnect density, one or more of the second, smaller size UBMs are formed as oblong-shaped UBMs. An oblong-shaped UBM is a UBM that has an elongated, first length in a first direction, and a smaller, second length less than the first length in a second direction orthogonal to the first direction. Examples of an oblong-shaped UBMs are elliptical-shaped UBMs and rectangular-shaped UBMs. Providing second, smaller size UBMs as oblong-shaped UBMs can support a further reduction in UBM pitch, because a minimum distance provided between adjacent oblong-shaped UBMs that is based on the minimum pitch process limitations of the corresponding coupled metal interconnects in the package substrate can be maintained. In this manner, being able to provide second, smaller size UBMs not only in the core area of the die, but as oblong-shaped UBMs, can provide even greater flexibility in the circuit layout design of the die, and/or be used to reduce die area and/or to provide even greater die interconnect density.

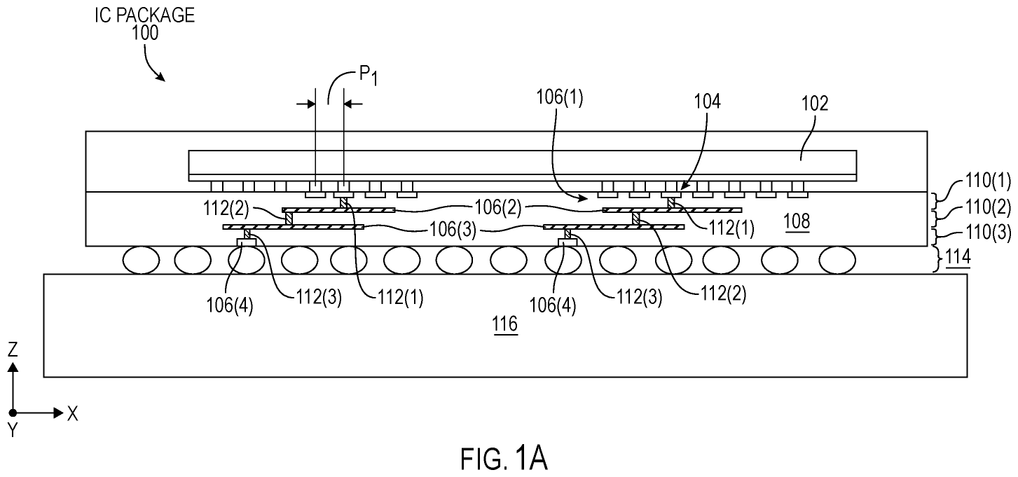

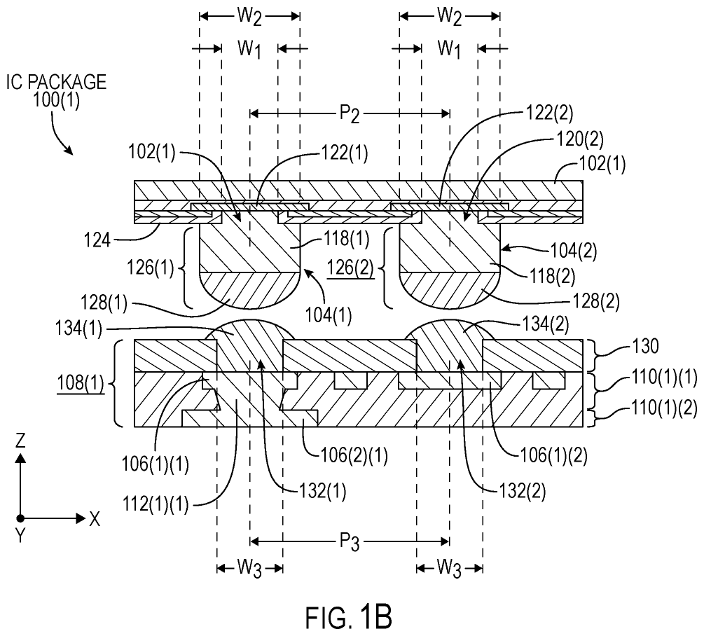

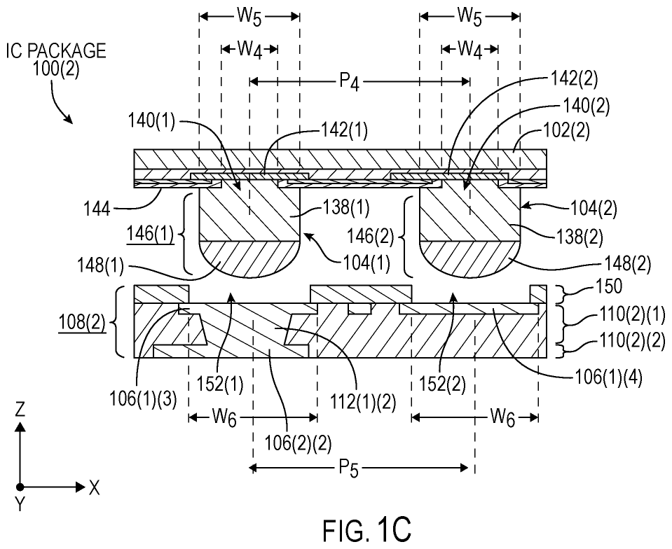

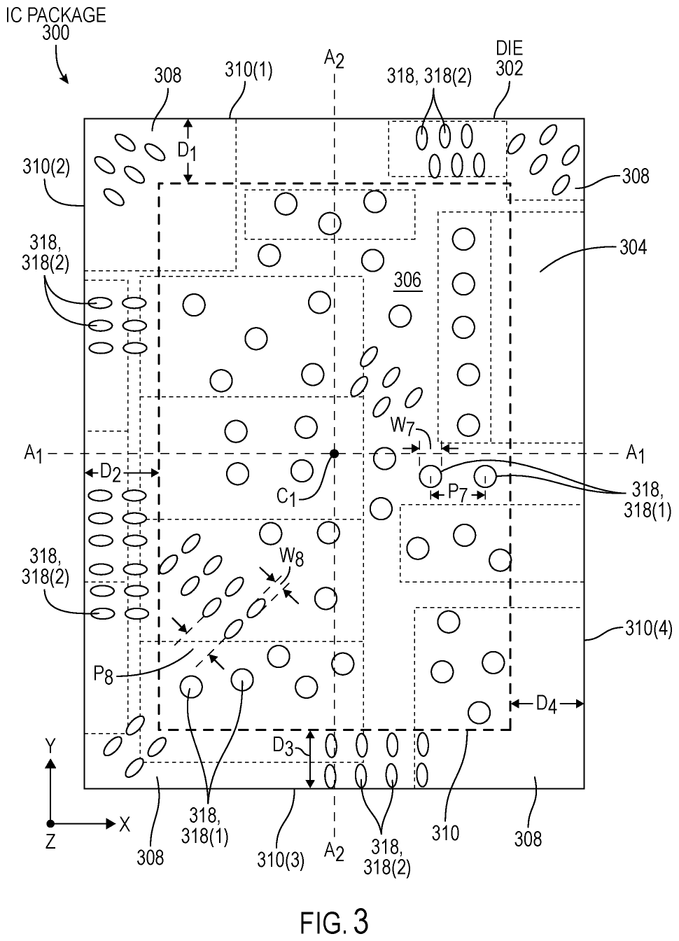

Examples of IC packages that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die start at FIG. 3 discussed below. Before discussing these examples of IC packages, an IC package 100 in FIGS. 1A-1C is first discussed below.

In this regard, FIG. 1A is a cross-sectional side view of an exemplary integrated circuit (IC) package 100 that includes a semiconductor die (“die”) 102 with die interconnects 104 coupled to corresponding first metal interconnects 106(1) in a package substrate 108. As will be discussed below, the die interconnects 104 include UBMs that have raised interconnect bumps (e.g., copper bumps) formed thereon to facilitate coupling between the die 102 and the package substrate 108. The die interconnects 104 are formed on the die 102 at a desired interconnect bump pitch according to the signaling density needed for the application of the IC package 100 and fabrication process limitations. The package substrate 108 includes a first, outer metallization layer 110(1) that includes the first metal interconnects 106(1) that are exposed to be able to be coupled to the die interconnects 104. As discussed below, the first and second metal interconnects 106(1), 106(2) can be coupled to the raised interconnect bumps of the die interconnects 104 to provide signal routing paths between the die 102 and the package substrate 108. The package substrate 108 in this example also includes additional second and third metallization layers 110(2), 110(3) that include respective second and third metal interconnects 106(2), 106(3) to provide additional signal routing in the package substrate 108. Vias 112(1)-112(3) can be included in the package substrate 108 to couple the first, second, and third metal interconnects 106(1)-106(3) between adjacent first, second, and third metallization layers 110(1)-110(3) for signal routing. Fourth metal interconnects 106(4) can be coupled to external interconnect bumps 114 (e.g., solder bumps, ball grid arrays (BGAs), land grid arrays (LGAs)) that are external to the IC package 100 to facilitate coupling of the IC package 100 to a circuit board 116, such as a printed circuit board (PCB). In this manner, the package substrate 108 and the die interconnects 104 provide signal routing paths between the die 102 and the external interconnect bumps 114 to the circuit board 116. Also, some of the raised die interconnects 104 may be coupled to the same first metal interconnects 106(1) in the package substrate 108 to further lower resistance. For example, this may be desired for power signal routing paths to reduce current-resistance (IR) drop.

The pitch P₁ of the die interconnects 104 in the die 102 in FIG. 1A that are coupled to the package substrate 108 influences the size of the die 102. For example, if the die 102 requires a larger density of die interconnects 104, this requires the die 102 to have a larger die area in the horizontal directions (X-Y axis plane) than if the die 102 had a smaller density of die interconnects 104 for a given pitch P₁ of the die interconnects 104. Thus, it may be desired to reduce the pitch P₁ of the die interconnects 104 to conserve area of the die 102 and thus conserve the overall size of the IC package 100. However, reducing the pitch P₁ of the die interconnects 104 can be challenging in IC package designs. Some IC packages, such as those involving RF technology, may have a larger number of bump keep-out-zones (KOZs). Also, reducing the pitch P₁ of the die interconnects 104 in the die 102 is sometimes not possible given package fabrication process limitations of the package substrate 108. Even when realization of reduced pitch P₁ of the die interconnects 104 in the die 102 in the IC package 100 is possible within fabrication process limitations, reduced pitch P₁ of the die interconnects 104 can cause a reduction in yield of the IC package 100 as well as higher assembly costs.

To reduce the pitch P₁ of the die interconnects 104 in the die 102, a solder-on-pad (SOP) process can be used to couple the die 102 to the package substrate 108 in FIG. 1A. This is shown in an exemplary cross-sectional view of an IC package 100(1) in FIG. 1B that can be the IC package 100 in FIG. 1A. The IC package 100(1) in FIG. 1B shows a cross-sectional view of a die 102(1), that can be the die 102 in FIG. 1A, before being coupled to an exemplary package substrate 108(1), that can be the package substrate 108 in FIG. 1A. As shown in FIG. 1B, die interconnects 104(1), 104(2) of the die 102(1) include UBMs 118(1), 118(2) that are formed at a given pitch P₂. The UBMs 118(1), 118(2) are formed in respective openings 120(1), 120(2) in the die 102(1) that expose respective metal pads 122(1), 122(2) in the die 102(1) from an outer surface 124 of the die 102(1), such that the UBMs 118(1), 118(2) contact the respective metal pads 122(1), 122(2). For example, the outer surface 124 of the die 102(1) may be an active surface that is adjacent to active devices formed within a semiconductor layer within the die 102(1). The UBMs 118(1), 112(2) are part of respective raised interconnect bumps 126(1), 126(2) that also include solder joints 128(1), 128(2) coupled to the respective UBMs 118(1), 118(2). Thus, the width W₁ of the openings 120(1), 120(2) affects the size (e.g., width W₂) of the UBMs 118(1), 118(2). Size of UBMs, such as UBMs 118(1), 118(2), refers to a two-dimensional area or other dimension of a UBM in the plane of the surface of the die in which the UBMs are coupled. For example, UBM size can be defined in terms of its overall area or other dimension such as diameter, length, and/or width, in the plane of the surface of the die in which the UBMs are coupled.

With continuing reference to FIG. 1B, the package substrate 108 includes a solder resist layer 130 that includes solder resist layer openings (SROs) 132(1), 132(2) each of width W₃. The solder resist layer openings 132(1), 132(2) expose respective first metal interconnects 106(1)(1), 106(1)(2) in a first, outer metallization layer 110(1)(1) of the package substrate 108(1). To couple the die interconnects 104(1), 104(2) of the die 102(1) to the first metal interconnects 106(1)(1), 106(1)(2) in the package substrate 108(1), a pre-solder step is performed in which a solder material is disposed in the solder resist layer openings 132(1), 132(2). The solder material in the solder resist layer openings 132(1), 132(2) and in contact with the first metal interconnects 106(1)(1), 106(1)(2) forms respective interconnect bumps 134(1), 134(2) (e.g., solder bumps). A reflow process can then be performed when the solder joints 128(1), 128(2) of the die interconnects 104(1), 104(2) are brought into contact with the respective interconnect bumps 134(1), 134(2) to couple the respective solder joints 128(1), 128(2) and interconnect bumps 134(1), 134(2) together, thus coupling the die 102(1) to the first metal interconnects 106(1)(1), 106(1)(2). The width W₂ of the UBMs 118(1), 118(2) is larger than the width W₃ of the solder resist layer openings 132(1), 132(2) to ensure good contact between the solder joints 128(1), 128(2) and the interconnect bumps 134(1), 134(2) in this example. Also in this example, the first metal interconnect 106(1)(1) is also shown coupled to a second metal interconnect 106(2)(1) in a second metallization layer 110(1)(2) through an intermediate via 112(1)(1).

In this manner, the pitch P₃ of the solder resist layer openings 132(1), 132(2) affects the minimum pitch P₂ of the UBMs 118(1), 118(2), because the pitch P₃ of the solder resist layer openings 132(1), 132(2) affects the formation of the interconnect bumps 134(1), 134(2) that are aligned and coupled to the UBMs 118(1), 118(2) through the solder joints 128(1), 128(2). It is important that a minimum pitch P₃ of the solder resist layer openings 132(1), 132(2) be maintained to prevent shorting of the interconnect bumps 134(1), 134(2). However, the interconnect bumps 134(1), 134(2) that extend outside of the solder resist layer openings 132(1), 132(2) allow the UBMs 118(1), 118(2) to be coupled to the package substrate 108 outside of the solder resist layer openings 132(1), 132(2) to provide for a reduced pitch P₂ of the UBMs 118(1), 118(2), because the UBMs 118(1), 118(2) do not have to extend into the solder resist layer openings 132(1), 132(2) to be coupled to the first metal interconnects 106(1)(1), 106(1)(2) because of the interconnect bumps 134(1), 134(2). However, the SOP process in FIG. 1B requires the solder resist layer 130 and an additional reflow process to couple the interconnect bumps 134(1), 134(2) to the solder joints 128(1), 128(2) of the die interconnects 104(1), 104(2) of the die 102(1).

FIG. 1C illustrates a cross-sectional view of another IC package 100(2), that can be the IC package 100 in FIG. 1A. The IC package 100(2) in FIG. 1C uses a bond-on-pad process to couple a die 102(2), which can be the die 102 in FIG. 1A, to an exemplary package substrate 108(2), that can be the package substrate 108 in FIG. 1A. The IC package 100(2) in FIG. 1C shows a cross-sectional view of the die 102(2) before being coupled to the package substrate 108(2). As shown in FIG. 1C, the die interconnects 104(1), 104(2) of the die 102(2) include UBMs 138(1), 138(2) that are formed at a given pitch P₄. The UBMs 138(1), 138(2) are formed in respective openings 140(1), 140(2) in the die 102(2) that expose respective metal pads 142(1), 142(2) in the die 102(2) from an outer surface 144 of the die 102(2). The UBMs 138(1), 138(2) contact the respective metal pads 142(1), 142(2). To couple raised interconnect bumps 146(1), 146(2) and their UBMs 138(1), 138(2) of the die 102(2) to the first metal interconnects 106(1)(3), 106(1)(4) in the package substrate 108(2), solder joints 148(1), 148(2) of the raised interconnect bumps 146(1), 146(2) are disposed inside solder resist layer openings 152(1), 152(2) of width W₆ in a solder resist layer 150. The solder joints 148(1), 148(2) are brought into direct contact to the first metal interconnects 106(1)(3), 106(1)(4) as a “bond-on-pad.” Also in this example, the first metal interconnect 106(3)(1) is also shown coupled to a second metal interconnect 106(2)(2) in a second metallization layer 110(2)(2) through an intermediate via 112(1)(2). Interconnect bumps, like the interconnect bumps 134(1), 134(2) in the IC package 100(1) in FIG. 1B, are not employed.

In this manner, the need for the solder joints and a solder reflow process is not necessary. However, the width W₅ of the UBMs 138(1), 138(2) is smaller than the width W₆ of the solder resist layer openings 152(1), 152(2) in the solder resist layer 150 in this example so that the die interconnects 104(1), 104(2) can be disposed inside the solder resist layer openings 152(1), 152(2). However, the minimum pitch P₄ of the UBMs 138(1), 138(2) in the IC package 100(2) in FIG. 1C is larger than the minimum pitch P₂ of the UBMs 118(1), 118(2) in the IC package 100(1) in FIG. 1B. This is because the width W₆ of the solder resist layer openings 152(1), 152(2) in FIG. 1C is larger than the width W₃ of the solder resist layer openings 132(1), 132(2) in FIG. 1B for the die interconnects 104(1), 104(2) to be disposed inside the solder resist layer openings 152(1), 152(2). Because the width W₆ of the solder resist layer openings 152(1), 152(2) in FIG. 1C is larger, this increases the minimum pitch P₅ of the solder resist layer openings 152(1), 152(2) to stay within process limitations for forming the solder resist layer openings 152(1), 152(2) and maintaining a minimum distance between the solder resist layer openings 152(1), 152(2), which in turn increases the minimum pitch P₄ of the UBMs 138(1), 138(2).

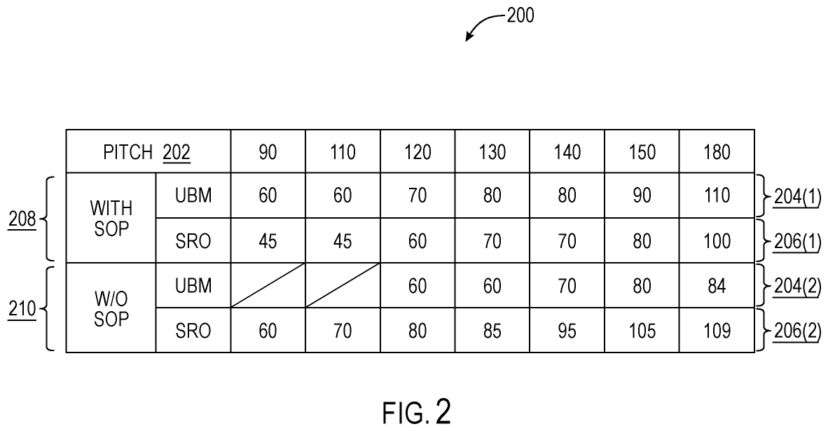

Thus, using the bond-on-pad process to couple the die 102 to the package substrate 108 in FIG. 1A may avoid the need for forming solder joints in a solder resist layer and performing a solder reflow process. However, the bond-on-pad process may increase the minimum pitch of the UBMs in the die 102 in an undesired manner. It may be desired to decrease the minimum pitch of the UBMs in a die, such as the die 102 in FIG. 1A, to support an increased die interconnect density and/or to conserve die area. This is shown in table 200 in FIG. 2, which illustrates exemplary minimum UBM pitches 202 for UBMs in a die for a given UBM size 204(1), 204(2) (e.g., width) and solder resist layer opening (SRO) size 206(1), 206(2) (e.g., width) for a respective SOP process 208 and bond-on-pad process 210, all in micrometers (μm). As shown in FIG. 2, if it is desired to have a minimum UBM pitch of 120 μm, in the SOP process 208, the UBM size 204(1) may be 70 μm, and the SRO size 206(1) may be less at 60 μm, because as discussed above, the UBM does not have to be sized to fit inside the SRO for a SOP process 208. However, as also shown in FIG. 2, if it desired to have the same minimum UBM pitch 202 of 120 μm for a bond-on-pad process 210, the SRO size 206(2) may be larger at 80 μm to allow for a 60 μm UBM size 204(2) to be able to fit inside of the larger SRO size 206(2). It may not be possible to reduce the minimum UBM pitch 202 below 120 μm for a bond-on-pad process 210, because this would mean that the SRO size 206(2) would have to be less than 60 μm. Otherwise, reliability issues in the coupling between the UBM and the package substrate may result from the UBM size 204(2) being too small where stresses imparted on the UBM from forces, such as warpage, could break or decouple the UBM from the package substrate and/or its die.

Thus, in one non-limiting example, it may be desired to be able to avoid or not require a SOP process to couple a die to a package substrate, but also allow for die interconnects to be provided of a reduced size and minimum pitch (e.g., below 120 μm) without sacrificing reliability issues in the coupling between the UBM and the package substrate. This may be particularly desired if it is desired to have the flexibility of providing mixed UBM sizes in a die for routing of different types of signals to minimize die area and thus the size of the IC package and/or increase die interconnect density. Providing mixed UBM sizes in a die for routing of different types of signals can provide greater flexibility in the design and layout of the die, because different circuits within the die (e.g., power-related circuits and I/O-related circuits) may only require coupling to smaller size UBMs for performance requirements and thus can be more flexibly located in the die. Thus, if such smaller size UBMs can be provided in a die for connection to circuits in the die that do not require larger-sized UBMs that are of a reduced pitch, this supports increased die interconnect density and/or reduced die area.

In this regard, FIG. 3 is a bottom view of an exemplary die 302 that can be provided in an IC package 300, wherein the die 302 includes UBMs 318 in a UBM pattern that are part of die interconnects used to couple the die 302 to a substrate, such as a package substrate. A UBM is a layer of metal that formed in contact with metal pads in a semiconductor die to provide an electrical and mechanical connection of the die and a substrate, such as a package substrate. The die 302 in FIG. 3 can be the die 102 in FIG. 1A that is coupled to the package substrate 108. With reference to FIG. 3, the UBMs 318 are formed on an outer surface 304 of the die 302. The die 302 includes a core area 306 that is surrounded by a periphery area 308, separated by the dashed box 310 that signifies the boundary between the core area 306 and the periphery area 308. The core area of a die, such as the core area 306 of the die 302, refers to a centralized region of the die where the UBMs and/or their die bumps are located on the surface of the die for providing die interconnects. The periphery area of a die, such as the periphery area 308 of the die 302, refers to a region extending from edges of the die to and surrounding a core area of the die where UBMs and/or their die bumps can also be located on the surface of the die for providing die interconnects. The periphery area 308 of the die 302 extends to the die edges 310(1)-310(4) of the die 302 and extends inward partial distances D₁, D₂, D₃, D₄ from the respective die edges 310(1)-310(4) on the outer surface 304 towards the die center C₁. The periphery area 308 surrounds the core area 306 of the die 302. The core area 306 encompasses the die center C₁ in this example. The die center C₁ in this example, is the intersection of a first center axis A₁ that extends through the center of the die 302 between die edges 310(1), 310(3) in a first, horizontal direction (X-axis direction), and a second center axis A₂ that extends through the center of the die 302 between die edges 310(2), 310(4) in a second, horizontal direction (Y-axis direction) orthogonal to the first direction (X-axis direction).

As shown in FIG. 3, in this example, the UBMs 318 include a plurality of first UBMs 318(1) of a first, larger size W₇ (e.g., width or diameter W₇) and pitch P₇ that are located in the core area 306 of the die 302 in this example. The first UBMs 318(1) can be coupled to metal interconnects in a package substrate (e.g., the first metal interconnects 106(1) in the package substrate 108 in FIG. 1A) for routing signals in the core area 306 of the die 302. For example, the first UBMs 318(1) could be coupled to a package substrate using a bond-on-trace connection. For example, the first UBMs 318(1) could be used for routing of power distribution signals (e.g., power and ground signals) between a power distribution network in package substrate and the coupled die 302 for the benefit of reduced resistance. Also, the first UBMs 318(1) may need to be larger to support a connection to a larger complementary coupled first metal interconnect 106(1) that may need to be larger to support connection through a via to metal interconnects 106(2)-106(3) in other second and third metallization layers 110(2), 110(3), for example. As also shown in FIG. 3, the die 302 also includes second UBMs 318(2) of a second size W₈ (e.g., width or diameter W₈) and pitch P₈ smaller than the first size W₇ and pitch P₇ of the first UBMs 318(1). The second UBMs 318(2) can also be coupled to metal interconnects in the package substrate (e.g., the first metal interconnects 106(1) in the package substrate 108 in FIG. 1A) for routing signals to the die 302. Providing the second UBMs 318(2) of the second size W₈ (e.g., width or diameter W₈) and pitch P₈ smaller than the first size W₇ and pitch P₇ of the first UBMs 318(1) provides additional flexibility of increased die interconnect density in the die 302. For example, the second UBMs 318(2) could be used for routing of I/O signals between a package substrate and the coupled die 302, where providing larger size UBMs as the second UBMs 318(2) may not be necessary or needed for reduced resistance for performance of the die 302.

In this example, the size of the first and second UBMs 318(1), 318(2) refers to a two-dimensional area or other dimension of the first and second UBMs 318(1), 318(2) in the plane of the outer surface 304 of the die 302 in which the first and second UBMs 318(1), 318(2) are coupled. For example, the size of the first and second UBMs 318(1), 318(2) can be defined in terms of its overall area or other dimension such as diameter, length, and/or width, in the plane of the outer surface 304 of the die 302 in which the first and second UBMs 318(1), 318(2) are coupled. By indicating that the size of the second UBMs 318(2) is smaller than the size of the first UBMs 318(1), the second UBMs 318(2) have at least one dimension in the plane of the outer surface 304 of the die 302 that is smaller than at least one dimension of the first UBMs 318(1) in the plane of the outer surface 304 of the die 302.

As shown in FIG. 3, a subset of the second UBMs 318(2) is in the core area 306 of the die 302 for enhanced design and layout flexibility for the die 302. Providing the second UBMs 318(2) of the second size W₈ (e.g., width or diameter W₈) and pitch P₈ smaller than the first size W₇ and pitch P₇ of the first UBMs 318(1) in the core area 306 of the die 302 also provides additional flexibility in the design and circuit layout of the die 302. For example, in conventional dies, the UBMs dedicated for I/O signals may only be in the periphery area of the die, because the layout of the die provides for the routing of I/O signals adjacent to the die edges of the die. However, this also requires circuits in the die that support such I/O signals to possibly have to be located in or closer to the periphery area of the die, thus reducing circuit layout flexibility of the die. By being able to also provide for the smaller size, second UBMs 318(2) in the core area 306 of the die 302, the circuit layout of the die 302 may be more flexible. Also, as shown in FIG. 3, another subset of the second UBMs 318(2) is in the periphery area 308 of the die 302 for routing of signals to the periphery area 308 of the die 302.

As discussed above, it may be desired to provide the reduced pitch P8 of the second, smaller size UBMs 318(2) such as to have the flexibility to further reduce area of the die 302 and/or to increase die interconnect density. However, as also discussed above as an example, if a bond-on-pad process is employed to couple the die 302 to a package substrate, process limitations in the package substrate for providing the openings in a solder resist layer in which the die interconnects are disposed may provide a minimum solder resist layer opening pitch. This minimum solder resist layer opening pitch dictates the minimum pitch of the second, smaller size UBMs 318(2).

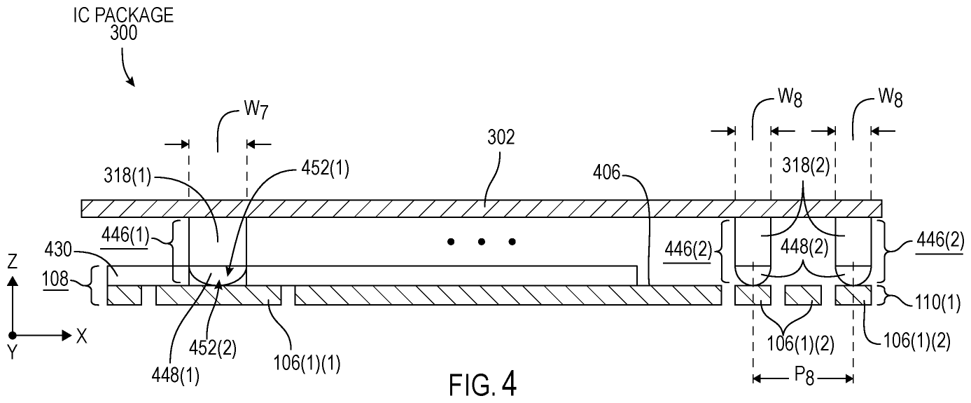

In this regard, as shown in FIG. 4, the second, smaller size UBMs 318(2) can be coupled to a package substrate in a “bond-on-trace” connection. FIG. 4 is a side, cross-sectional view of the IC package 300 in FIG. 3 that shows first and second die interconnects 446(1), 446(2) of the die 302 coupled to the outer, first metallization layer 110(1) of the package substrate 108 in FIG. 1. As shown in FIG. 4, a first die interconnect 446(1) that includes a first, larger size UBM 318(1) is coupled to the first metal interconnect 106(1)(1) in the first metallization layer 110(1) using a bond-on-pad process, like the bond-on-pad process described in FIG. 1C for example. The first interconnect bump 448(1) of the first die interconnect 446(1) that is coupled to the first UBM 318(1), is disposed in a first solder resist layer opening 452(1) of a solder resist layer 430 adjacent to the first metallization layer 110(1) and between the first metallization layer 110(1) and the die 302. The first interconnect bump 448(1) is placed in contact with the first metal interconnect 106(1)(1) to couple the first die interconnect 446(1) of the die 302 to the package substrate 108. The pitch P₇ of the first UBMs 318(1) may be equal to or slightly larger than the pitch of second solder resist layer openings 452(2) (see also, e.g., FIG. 1C).

Also, as shown in FIG. 4, second die interconnects 446(2) that include the second, smaller size UBMs 318(2) are coupled to first metal interconnects 106(1)(2) as first metal traces 106(1)(2) in the first metallization layer 110(1) using a bond-on-trace process. Metal traces are metal lines formed in a metal layer of a metallization layer. In this regard, the solder resist layer 430 is not present in the path, or adjacent thereto, of the second die interconnects 446(2) to the first metal traces 106(1)(2). The second interconnect bumps 448(2) of the second die interconnects 446(2), that are coupled to the second UBMs 318(2), are brought into contact with the first metal traces 106(1)(2). For example, the first metal traces 106(1)(2) are exposed from a top, first surface 406 of the first metallization layer 110(1) of the package substrate 108. In this manner, the process limitations of forming solder resist layer openings in the solder resist layer 430 are not limiting factors in the pitch P₈ of the second die interconnects 446(2) and their second UBMs 318(2). Also, because the solder resist layer 430 is not present in the area of contact between the second interconnect bumps 448(2) and the first metal traces 106(1)(2) using the bond-on-trace connection process, any process requirements on the width of the solder resist layer openings are not design factors for the design of the size W₈ and pitch P₈ of the second UBMs 318(2) in this example.

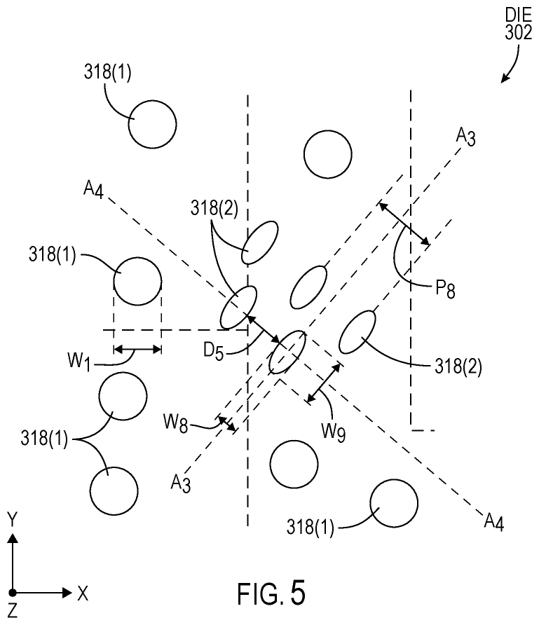

Also, in an example, and as shown in the die 302 in FIG. 3 and in a partial close-up view of the die 302 in FIG. 5, the second UBMs 318(2) can also be provided as second, oblong-shaped UBMs 318(2). In this regard, as shown in FIG. 5, the UBMs 318(2) have an elongated, first length or width W₉ in a first direction in the direction of a first axis A₃, and a smaller, second length or width W₈ less than the first length or width W₉ in a second direction in the direction of a second axis A₄ orthogonal to the first direction and first axis A₄. The first length or width W₉ of the second UBMs 318(2) may also be less than the width W₇ or diameter W₇ of the first UBMs 318(2). The UBMs 318(2) shown in FIG. 5 are oblong-shaped in the form of elliptical-shaped UBMs, but another example of a second, oblong-shaped UBM 318(2) is a rectangular-shaped UBM. Providing the second, smaller size UBMs 318(2) as second, oblong-shaped UBMs 318(2) can support a further reduction in the pitch P₈ of the second UBMs 318(2), because a minimum distance D₅ provided between adjacent second, oblong-shaped UBMs 318(2) based on the minimum pitch process limitations of the corresponding coupled metal interconnects 106(1)(2) in the package substrate 108 can be maintained. In this manner, being able to provide second, smaller size UBMs 318(2) not only in the core area 306 of the die 302, but as second, oblong-shaped UBMs 318(2), can provide even greater flexibility in the circuit layout design of the die 302, and/or be used to reduce the area of the die 302 and/or to provide even greater die interconnect density in the die 302.

In a non-limiting example, by providing the second UBMs 318(2) as second, oblong-shaped UBMs 318(2), the second, oblong-shaped UBMs 318(2) may be capable of being provided of a size or width W₉ less than or equal to one hundred ten (110) μm and smaller than the size W₇ or width W₇ or diameter W₇ of the first UBMs 318(2). Also, by providing the second UBMs 318(2) as second, oblong-shaped UBMs 318(2), the second, oblong-shaped UBMs 318(2) may be capable of being provided with a pitch P₈ less or equal to seventy (70) μm and less than the pitch P₇ of the first UBMs 318(1).

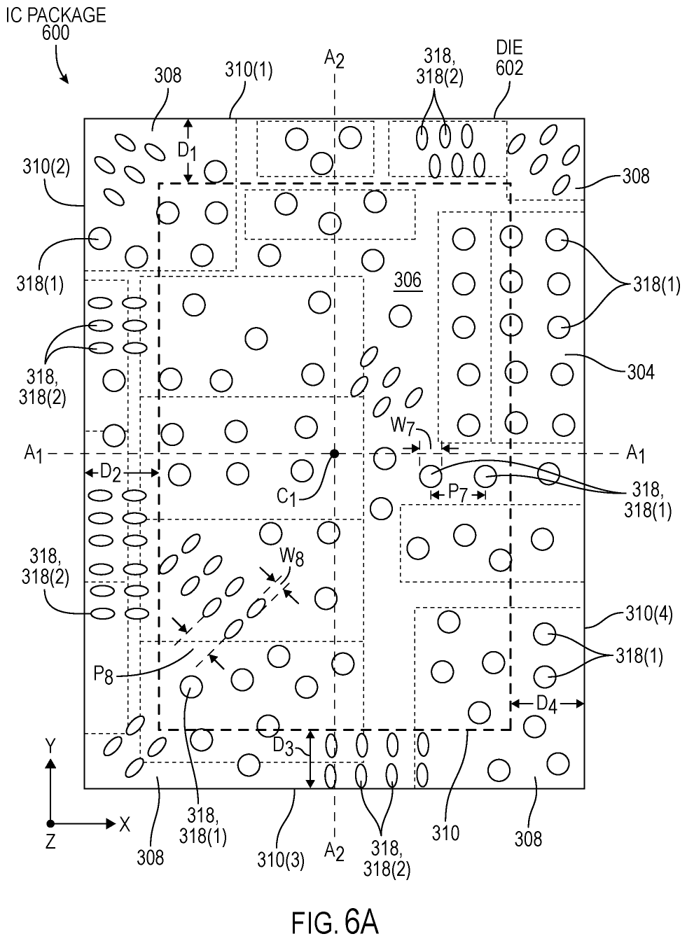

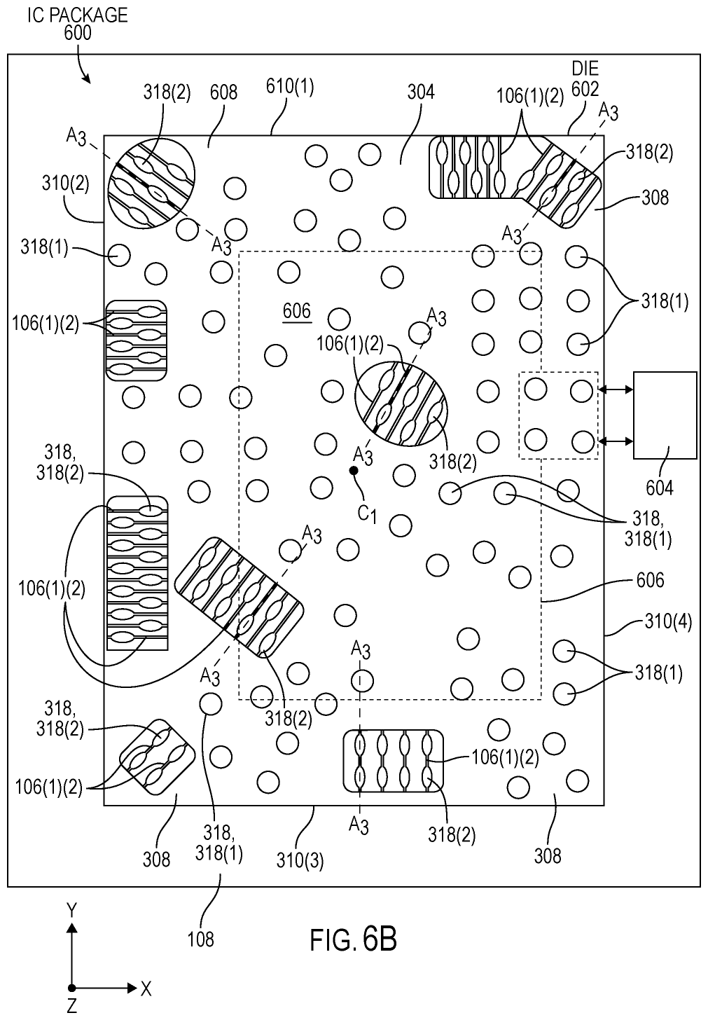

It also possible to provide a die that locates the first, larger size UBMs 318(1) outside the core area of a die and into the periphery area of the die. For example, it may be desired to provide a die that has a layout of circuits that are located at or near the periphery area of the die and thus more advantageously coupled, through die interconnects, to first, larger size UBMs 318(1) in the periphery area of the die. This is shown by example in the exemplary die 602 in the exemplary package substrate 600 in FIGS. 6A and 6B. Common elements between the die 602 in FIG. 6A and the die 302 in FIG. 3 are shown with common element numbers. However, as shown in the bottom view of the die 602 in FIG. 6A, a subset of the first, larger size UBMs 318(1) are also located in the periphery area 308 of the die 602. For example, it may be desired to provide a subset of first, larger size UBMs 318(1) in the periphery area 308 of the die 302 to reduce connection length to a coupled component 604 (e.g., a capacitor or inductor for power conditioning) on the package substrate 108 adjacent to the die 602 as shown in FIG. 6B.

FIG. 6B is a top view of the IC package 600 in FIG. 6A that includes the die 302 in FIG. 6A coupled to the package substrate 108. As shown in FIG. 6B, the second UBMs 318(2) are second, oblong-shaped UBMs 318(2) that are coupled to first metal traces 106(1)(2) in the package substrate 108. Also, as shown in FIG. 6B, some of the second, smaller size oblong-shaped UBMs 318(2) are oriented in the die 602 such that their elongated axes A₃ are oriented in a direction towards the center area 606 of the die 602. The center area 606 of the die 602 is an area that is inward from the die edges 310(1)-310(4) in the core area 306 of the die 602 and surrounds the die center C₁. The center area 606 could be co-extensive with the core area 306 of the die 602. Some of the elongated axes A₃ of the second, oblong-shaped UBMs 318(2) directly intersect the die center C₁ of the die 602. In this manner, when a stress force is applied to the second, oblong-shaped UBMs 318(2) by their coupling to the package substrate 108, such as due to warpage that may be a result of a mismatch in coefficients of thermal expansion (CTEs) between the second, oblong-shaped UBMs 318(2) and the package substrate 108, at least some of the stress is applied to the second, smaller size oblong-shaped UBMs 318(2) in the direction of their elongated axes A₃. This causes the stress to be applied to a greater area of the second, smaller size oblong-shaped UBMs 318(2) to resist breakage or decoupling from the package substrate 108 and/or the die 602. This can better maintain the integrity of the coupling of the second, smaller size oblong-shaped UBMs 318(2) to the package substrate 108 and/or the die 602 in the presence of warpage or other forces to better maintain the integrity of the IC package 600.

The first, larger size UBMs and/or second, smaller size, oblong-shaped UBMs can also be provided in different shapes in different patterns that include some or all second, oblong-shaped UBMs depending on the bump pattern of a die. For example, if a UBM of a die is for routing power signals, the UBM may be coupled to a corresponding metal interconnect in a package substrate that does not need to be a larger size metal interconnect. For example, not every metal interconnect in the package substrate that is used to route power may need to be larger to support via connections to lower-level metal interconnects in the package substrate.

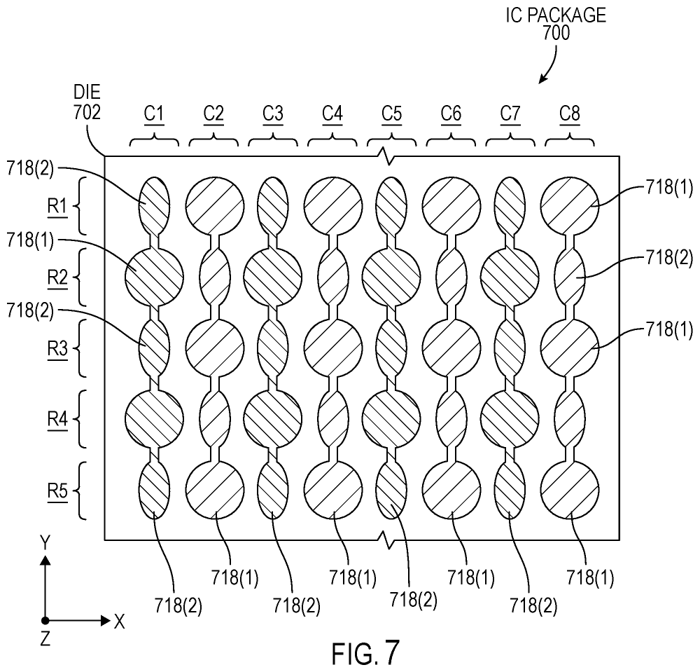

In this regard, FIG. 7 is a bottom view of an exemplary mixed UBM pattern 700 in a die 702, that can be any of the dies 102, 302, 602 in FIGS. 1A, 3, and 6A-6B as examples. As shown in FIG. 7, the die 702 includes columns C1-C8 and rows R1-R5 of adjacent third, symmetrical-shaped UBMs 718(1) and second, oblong-shaped UBMs 718(2) in an alternating pattern. A third, symmetrical-shaped UBM 718(1) is a UBM that has corresponding points whose connected lines are bisected by a given point or perpendicularly bisected by a given line or plane. For example, a third, symmetrical-shaped UBM 718(1) may be a circular UBM, a square UBM, or other regular polygon UBM. In this example, each row R1-R5 in the UBM pattern 700 has a plurality of the third, symmetrical-shaped UBMs 718(1) each disposed between two adjacent second, oblong-shaped UBMs 718(2) in its given row R1-R5. Also, in this example, each column C1-C8 in the UBM pattern 700 has a plurality of the third, symmetrical-shaped UBMs 718(1) each disposed between two adjacent second, oblong-shaped UBMs 718(2) in its given column C1-C8. In this manner, this mixed UBM pattern 700 provides an option to reduce UBM pitch where needed, but with relaxed fabrication processes that control metal interconnect pitch in the coupled substrate.

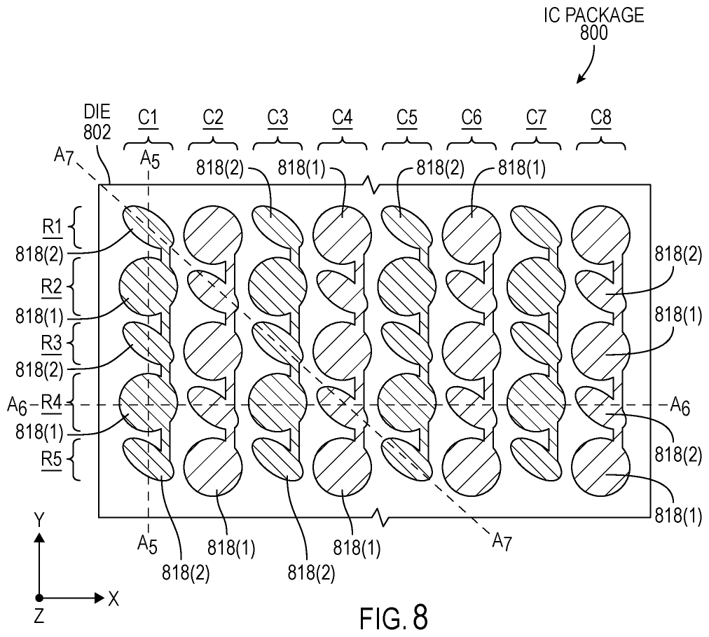

FIG. 8 is a bottom view of another exemplary mixed UBM pattern 800 in a die 802, that can be any of the dies 102, 302, 602 in FIGS. 1A, 3, and 6A-6B as examples. As shown in FIG. 8, the die 802 includes columns C1-C8 and rows R1-R5 of adjacent third, symmetrical-shaped UBMs 818(1) and second, oblong-shaped UBMs 818(2) also in an alternating pattern. In this example, each row R1-R5 in the UBM pattern 800 has a plurality of the third, symmetrical-shaped UBMs 818(1) each disposed between two adjacent second, oblong-shaped UBMs 818(2) in its given row R1-R5. Also, in this example, each column C1-C8 in the UBM pattern 800 has a plurality of the third, symmetrical-shaped UBMs 818(1) each disposed between two adjacent second, oblong-shaped UBMs 818(2) in its given column C1-C8. The third, symmetrical-shaped UBMs 818(1) each have fifth axis A₅ in their respective columns C1-C8 in a second, horizontal direction (Y-axis direction), and a sixth axis A₆ perpendicular to the fifth axis A₅ in their respective rows R1-R8 in a first, horizontal direction (Z-axis direction). The second, oblong-shaped UBMs 818(2) are oriented with their elongated length along a seventh axis A₇ in a third direction that is non-perpendicular (e.g., at an acute or obtuse angle) to the fifth and sixth axes A₅, A₆. In this manner, this mixed UBM pattern 800 provides an option to reduce UBM pitch where needed, but with relaxed fabrication processes that control metal interconnect pitch in the coupled substrate.

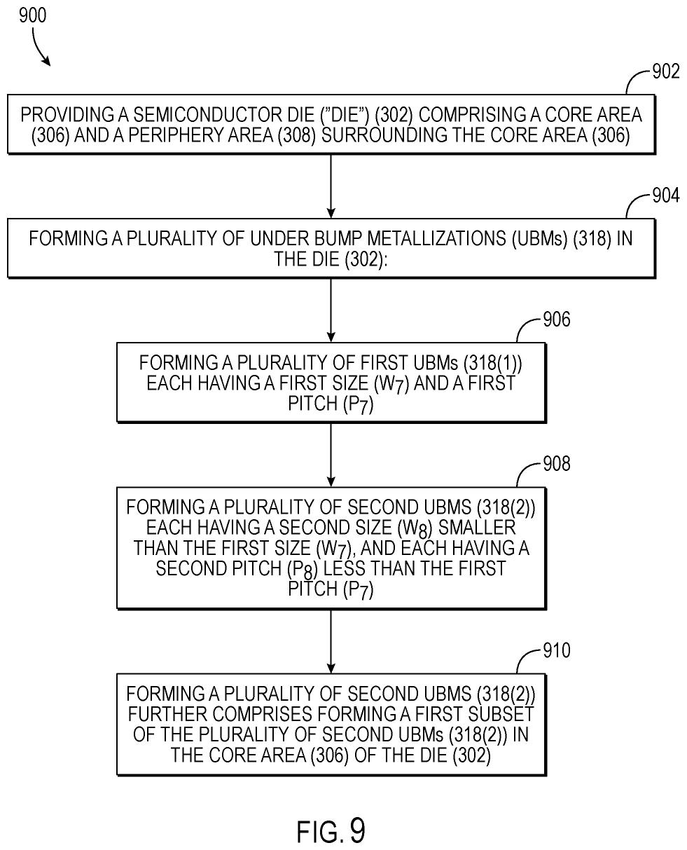

Fabrication processes can be employed to fabricate a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages and dies in FIGS. 3-8. In this regard, FIG. 9 is a flowchart illustrating an exemplary fabrication process 900 for fabricating a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602 in FIGS. 1A, 3, and 6A-6B. The fabrication process 900 in FIG. 9 will be described in conjunction with the exemplary die 302 in FIG. 3, but note that the fabrication process 900 in FIG. 9 is not limited to fabricating the die 302 in FIG. 3 and could be used to fabricate the dies 102, 602, 702, 802 in FIGS. 1A, 6A-6B, and 7-8.

In this regard, as illustrated in FIG. 9, a first step in the fabrication process 900 can include providing a semiconductor die (“die”) 302 comprising a core area 306 and a periphery area 308 surrounding the core area 306 (block 902 in FIG. 9). A next step in the fabrication process 900 can include forming a plurality of UBMs 318 in the die 302 (block 904 in FIG. 9). Forming the plurality of UBMs 318 in the die 302 can include forming a plurality of first UBMs 318(1) each having a first size W₇ and a first pitch P₇ (block 906 in FIG. 9). Forming the plurality of UBMs 318 in the die 302 can also include forming a plurality of second UBMs 318(2) each having a second size W₈ smaller than the first size W₇, and each having a second pitch P₈ less than the first pitch P₇ (block 908 in FIG. 9). Forming the plurality of second UBMs 318(2) can also include forming a first subset of the plurality of second UBMs 318(2) in the core area 306 of the die 302 (block 910 in FIG. 9).

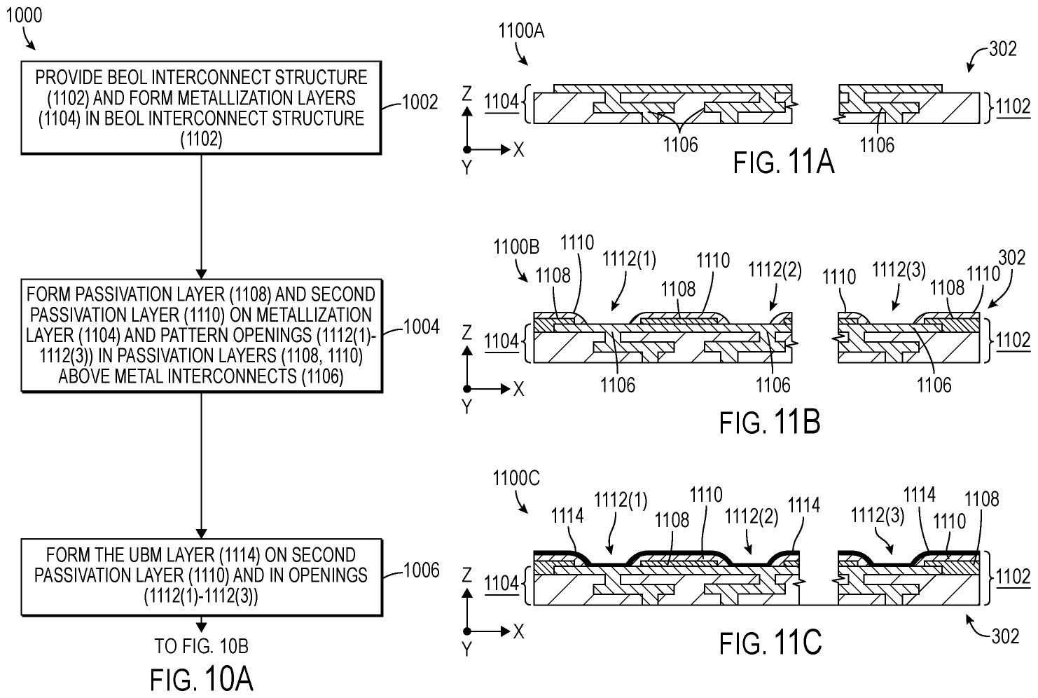

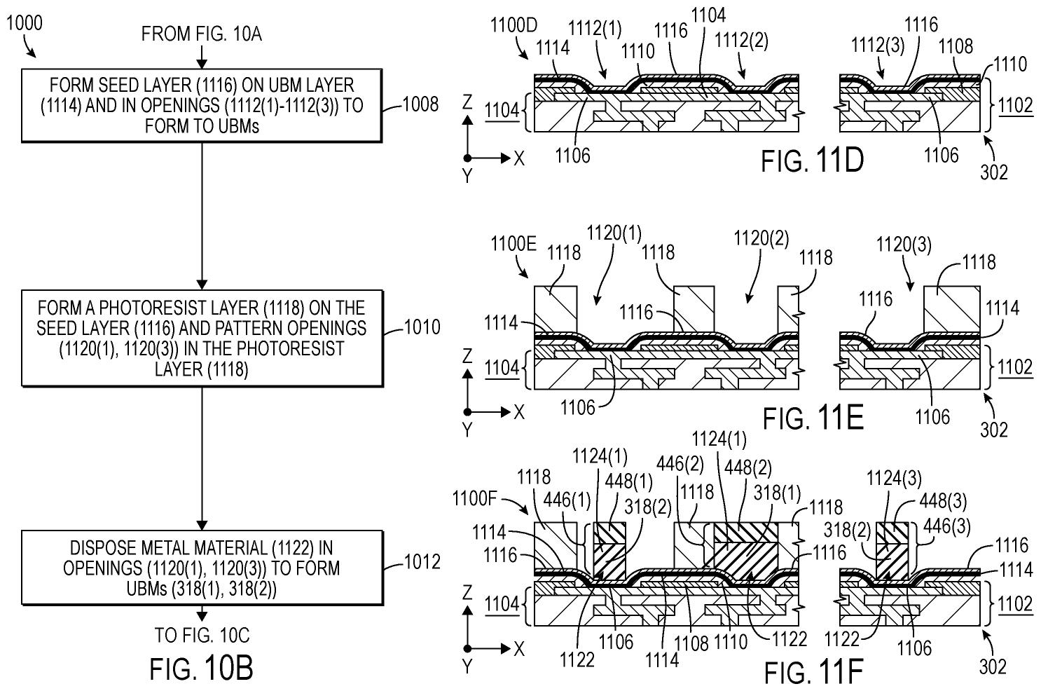

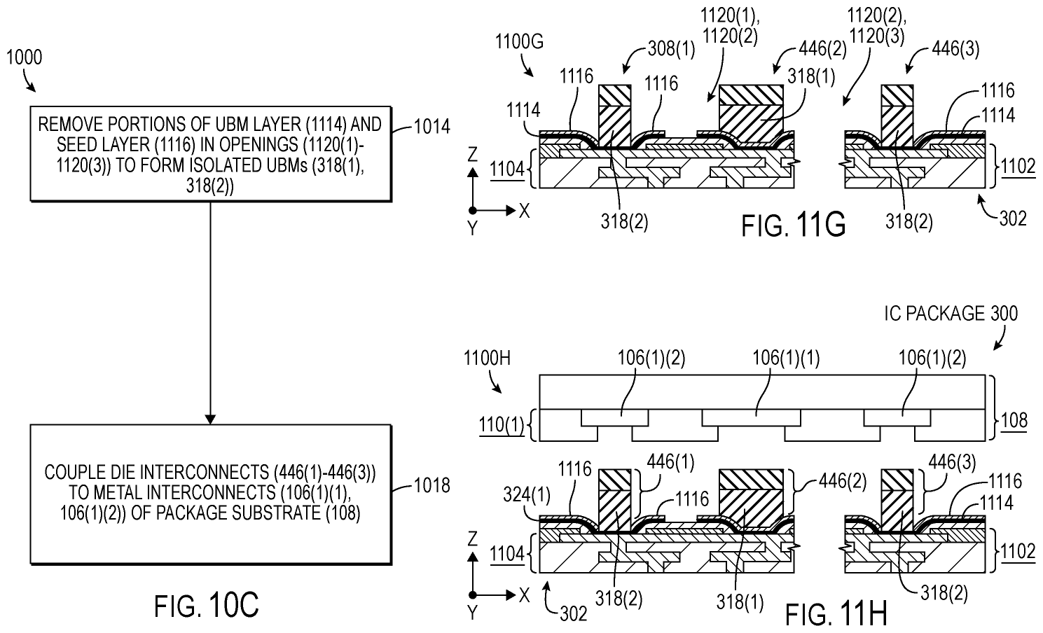

Other fabrication processes can also be employed to fabricate an IC package and/or die a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602 in FIGS. 3-8. In this regard, FIGS. 10A-10C is a flowchart illustrating another exemplary fabrication process 1000 of fabricating an IC package that includes a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602 in FIGS. 3-8. FIGS. 11A-11H illustrate exemplary fabrication stages 1100A-1100H in the fabrication process 1000 in FIGS. 10A-10C. The fabrication process 1000 in FIGS. 10A-10C will now be discussed in conjunction with the exemplary fabrication stages 1100A-1100I in FIGS. 11A-11H using the IC package 300 in FIGS. 3 and 4 as an example. However, note that the fabrication process 1000 in FIGS. 10A-10C represented by the fabrication stages 1100A-1100H in FIGS. 11A-11H could also be applicable to fabricate the other IC packages 100, 600, and their dies 102, 602 in FIGS. 1A and 6 as well.

In this regard, as shown in the exemplary fabrication stage 1100A in FIG. 11A, a first step in the fabrication process 1000 can be to provide a BEOL interconnect structure 1102 as part of the die 302 that includes metallization layers 1104 formed in the BEOL interconnect structure 1102 (block 1002 in FIG. 10A). Metal interconnects 1106 are exposed from the metallization layers 1104 that are coupled the UBMs 318(1), 318(2) of the die 302 to be formed. As shown in the exemplary fabrication stage 1100B in FIG. 11B, a next step in the fabrication process 1000 can be to form a passivation layer 1108 and a second passivation layer 1110 on the metallization layers 1104 and to pattern the passivation layers 1108, 1110 to form openings 1112(1)-1112(3) in the passivation layers 1108, 1110 above the metal interconnects 1106 (block 1004 in FIG. 10A). As shown in the exemplary fabrication stage 1100C in FIG. 11C, a next step in the fabrication process 1000 can be to form a UBM layer 1114 over the passivation layer 1110 to prepare for the UBMs 318(1), 318(2) of different sizes and/or pitches to be formed in the respective openings 1112(1)-1112(3) with interconnect bumps formed thereon (block 1006 in FIG. 10A).

Then, as shown in the exemplary fabrication stage 1100D in FIG. 11D, a next step in the fabrication process 1000 can be to form a seed layer 1116 on the UBM layer 1114 and in the openings 1112(1)-1112(3) to form the UBMs 318(1), 318(2) in the openings 1112(1)-1112(3) in contact with the metal interconnects 1106 (block 1008 in FIG. 10B). As shown in the exemplary fabrication stage 1100E in FIG. 11E, a next step in the fabrication process 1000 can be to form a photoresist layer 1118 on the seed layer 1116 and pattern openings 1120(1)-1120(3) in the photoresist layer 1118 to prepare to form the UBMs 318(1), 318(2) (block 1010 in FIG. 10B). The openings 1120(1)-1120(3) are patterned to provide for the UBMs 318(1), 318(2) to be formed and in contact with the metallization layers 1104 to be varied in size to provide different-sized UBMs 318(1), 318(2) (e.g., width W₇ and width W₈ as shown in FIG. 4) as previously discussed. The photoresist layer 1118 can be patterned in a lithography process to form the openings 1120(1)-1120(3) each disposed in a vertical direction (Z-axis direction) exposing the seed layer 1116 disposed in the openings 1112(1)-1112(3) in the metallization layer 1104. As illustrated in the exemplary fabrication stage 1100F in FIG. 11F, a next step in the fabrication process 1000 is to dispose a metal material 1122 in the openings 1120(1)-1120(3) in the photoresist layer 1118 to form the UBMs 318(1), 318(2) (block 1012 in FIG. 10B). Interconnect bumps 448(1)-448(3) are formed on the UBMs 318(1), 318(2) to form the die interconnects 446(1)-446(3). The portion of the seed layer 1116 and the UBM layer 1114 disposed in the openings 1112(1)-1112(3) also form part of the UBMs 318(1), 318(2).

Then, as shown in the exemplary fabrication stage 1100G in FIG. 11G, portions of the UBM layer 1114 and seed layer 1116 in the openings 1120(1)-1120(3) are removed (e.g., etched) to provide an open circuit between the UBMs 318(1), 318(2) for isolation (block 1014 in FIG. 10C). The decoupled UBMs 318(1), 318(2) are formed in this example as a result of the etching into the openings 1120(1)-1120(3). Then, as shown in the exemplary fabrication stage 1100H in FIG. 11H, the die interconnects 446(1)-446(3) of the die 302, that include the UBMs 318(1), 318(2) are ground into direct contact with metal interconnects 106(1)(1), 106(1)(2) in the first, outer metallization layer 110(1) of the package substrate 108 to couple the die 302 to the package substrate 108 to form the IC package 300 (block 1018 in FIG. 10C).

Note that the terms “top” and “bottom” where used herein are relative terms and are not meant to limit or imply a strict orientation that a “top” referenced element must always be oriented to be above a “bottom” referenced element, and vice versa. Also, note that the terms “above” and “below” where used herein are relative terms and are not meant to limit or imply a strict orientation that an element referenced as being “above” another referenced element must always be oriented to be above the other referenced element with respect to ground, or that an element referenced as being “below” another referenced element must always be oriented to be below the other referenced element with respect to ground.

An object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

IC packages provided in one or more IC packages that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602, 702, 802 in FIGS. 3-8, and 11A-11H and according to the exemplary fabrication processes 900, 1000 in FIGS. 9 and 10A-10C, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

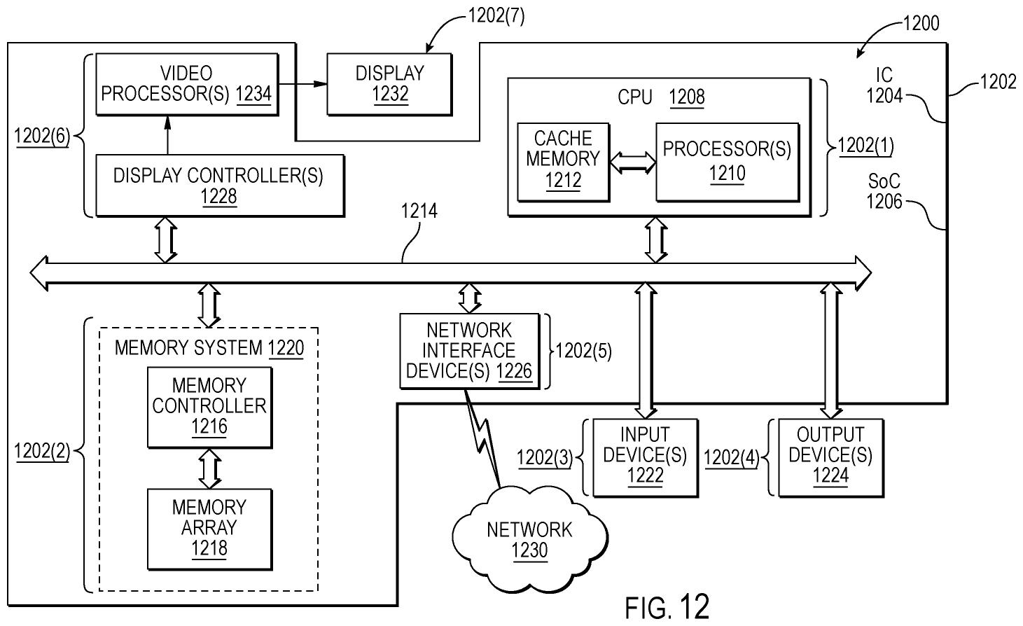

In this regard, FIG. 12 illustrates an example of a processor-based system 1200 that can be provided in or include one or more IC packages 1202(1)-1202(7) that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602, 702, 802 in FIGS. 3-8, and 11A-11H and according to the exemplary fabrication processes 900, 1000 in FIGS. 9 and 10A-10C. In this example, the processor-based system 1200 may be formed as an IC 1204 in an IC package 1202 as a system-on-a-chip (SoC) 1206. The processor-based system 1200 includes a central processing unit (CPU) 1208 that includes one or more processors 1210, which may also be referred to as CPU cores or processor cores. The CPU 1202 may be provided as an IC package 1202(1). The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216 as an example of a slave device. Although not illustrated in FIG. 12, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. The memory system 1220 may be provided as an IC package 1202(2). Each of the memory system 1220, the one or more input devices 1222, the one or more output devices 1224, the one or more network interface devices 1226, and the one or more display controllers 1228 can be provided in the same IC package 1202 or different respective IC packages 1202(3), 1202(4), 1202(5), 1202(6). The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display(s) 1232 may be provided as an IC package 1202(7). The display controller(s) 1228 sends information to the display(s) 1232 to be displayed via one or more video processors 1234, which process the information to be displayed into a format suitable for the display(s) 1232. The display controller(s) 1228 and video processor(s) 1234 can be included as ICs in the same IC package 1202(5), and in the same IC package 1202(6) or IC package 1202(1) containing the CPU 1208 as examples. The display(s) 1232 can include any type of display, including, but not limited to, a cathode ray tube (CRT), a liquid crystal display (LCD), a plasma display, a light emitting diode (LED) display, etc.

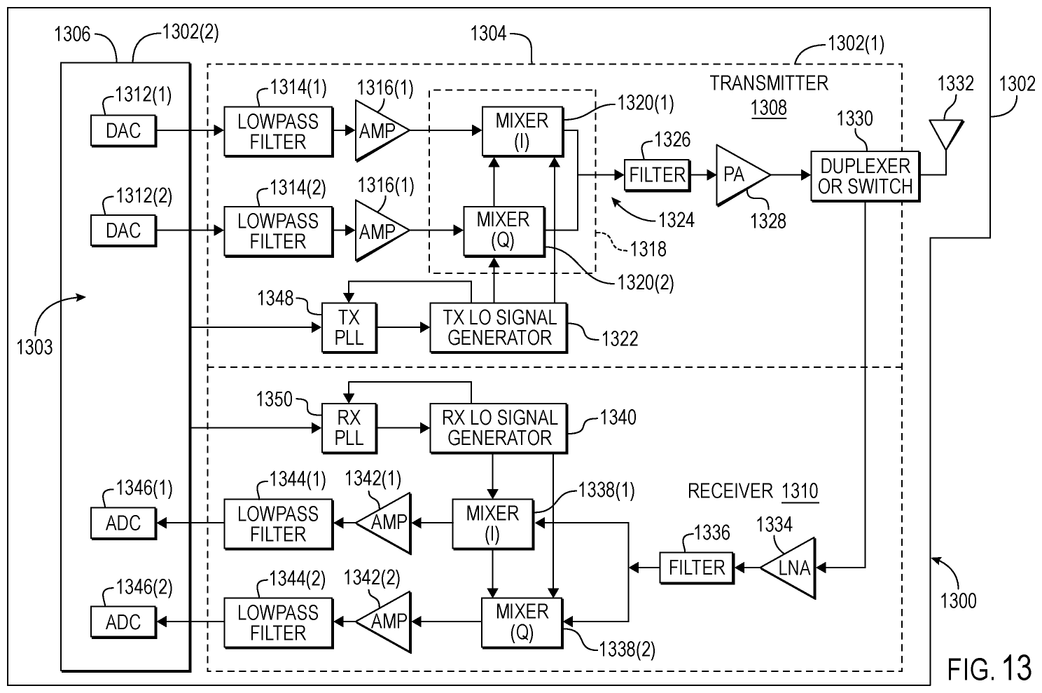

FIG. 13 illustrates an exemplary wireless communications device 1300 that includes RF components that can be provided in or include one or more IC packages 1302, 1302(1), 1302(2) that include a die that includes UBMs in a UBM pattern that includes first UBMs of a first, larger size and pitch, and second UBMs of a second, smaller size and pitch that are located in the periphery area(s) and core area of the die, to facilitate greater flexibility in the design and layout of the die, including, but not limited to, the IC packages 100, 300, 600 and dies 102, 302, 602, 702, 802 in FIGS. 3-8, and 11A-11H and according to the exemplary fabrication processes 900, 1000 in FIGS. 9 and 10A-10C. As shown in FIG. 13, the wireless communications device 1300 includes an RF transceiver 1304 and a data processor 1306. The components of the RF transceiver 1304 and/or data processor 1306 can be split among multiple different IC packages 1302(1), 1302(2). The data processor 1306 may include a memory to store data and program codes. The RF transceiver 1304 includes a transmitter 1308 and a receiver 1310 that support bi-directional communications. In general, the wireless communications device 1300 may include any number of transmitters 1308 and/or receivers 1310 for any number of communication systems and frequency bands. All or a portion of the RF transceiver 1304 may be implemented on one or more analog ICs, RFICs, mixed-signal ICs, etc.

The transmitter 1308 or the receiver 1310 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1310. In the direct-conversion architecture, a signal is frequency-converted between RF and baseband in one stage. The super-heterodyne and direct-conversion architectures may use different circuit blocks and/or have different requirements. In the wireless communications device 1300 in FIG. 13, the transmitter 1308 and the receiver 1310 are implemented with the direct-conversion architecture.

In the transmit path, the data processor 1306 processes data to be transmitted and provides I and Q analog output signals to the transmitter 1308. In the exemplary wireless communications device 1300, the data processor 1306 includes digital-to-analog converters (DACs) 1312(1), 1312(2) for converting digital signals generated by the data processor 1306 into the I and Q analog output signals, e.g., I and Q output currents, for further processing.

Within the transmitter 1308, lowpass filters 1314(1), 1314(2) filter the I and Q analog output signals, respectively, to remove undesired signals caused by the prior digital-to-analog conversion. Amplifiers (AMPs) 1316(1), 1316(2) amplify the signals from the lowpass filters 1314(1), 1314(2), respectively, and provide I and Q baseband signals. An upconverter 1318 upconverts the I and Q baseband signals with I and Q transmit (TX) local oscillator (LO) signals through mixers 1320(1), 1320(2) from a TX LO signal generator 1322 to provide an upconverted signal 1324. A filter 1326 filters the upconverted signal 1324 to remove undesired signals caused by the frequency upconversion as well as noise in a receive frequency band. A power amplifier (PA) 1328 amplifies the upconverted signal 1324 from the filter 1326 to obtain the desired output power level and provides a transmit RF signal. The transmit RF signal is routed through a duplexer or switch 1330 and transmitted via an antenna 1332.

In the receive path, the antenna 1332 receives signals transmitted by base stations and provides a received RF signal, which is routed through the duplexer or switch 1330 and provided to a low noise amplifier (LNA) 1334. The duplexer or switch 1330 is designed to operate with a specific receive (RX)-to-TX duplexer frequency separation, such that RX signals are isolated from TX signals. The received RF signal is amplified by the LNA 1334 and filtered by a filter 1336 to obtain a desired RF input signal. Downconversion mixers 1338(1), 1338(2) mix the output of the filter 1336 with I and Q RX LO signals (i.e., LO_I and LO_Q) from an RX LO signal generator 1340 to generate I and Q baseband signals. The I and Q baseband signals are amplified by AMPs 1342(1), 1342(2) and further filtered by lowpass filters 1344(1), 1344(2) to obtain I and Q analog input signals, which are provided to the data processor 1306. In this example, the data processor 1306 includes analog-to-digital converters (ADCs) 1346(1), 1346(2) for converting the analog input signals into digital signals to be further processed by the data processor 1306.

In the wireless communications device 1300 of FIG. 13, the TX LO signal generator 1322 generates the I and Q TX LO signals used for frequency upconversion, while the RX LO signal generator 1340 generates the I and Q RX LO signals used for frequency downconversion. Each LO signal is a periodic signal with a particular fundamental frequency. A TX phase-locked loop (PLL) circuit 1348 receives timing information from the data processor 1306 and generates a control signal used to adjust the frequency and/or phase of the TX LO signals from the TX LO signal generator 1322. Similarly, an RX PLL circuit 1350 receives timing information from the data processor 1306 and generates a control signal used to adjust the frequency and/or phase of the RX LO signals from the RX LO signal generator 1340.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A semiconductor die (die), comprising:
a core area;
a periphery area surrounding the core area; and
a plurality of under bump metallizations (UBMs), comprising:
   a plurality of first UBMs each having a first size and a first pitch; and
   a plurality of second UBMs each having a second size smaller than the first size, and each having a second pitch less than the first pitch;
   wherein:
      a first subset of the plurality of second UBMs is in the core area.

2. The die of clause 1, wherein a second subset of the plurality of second UBMs, different from the first subset of the plurality of second UBMs, is in the periphery area.

3. The die of clause 1 or 2, wherein a first subset of the plurality of first UBMs is in the periphery area.

4. The die of clause 3, wherein a second subset of the plurality of first UBMs is in the core area.

5. The die of any of clauses 1-4, wherein the plurality of second UBMs comprises a plurality of second, oblong-shaped UBMs that each have a first length along a first axis and a second length less than the first length along a second axis orthogonal to the first axis.

6. The die of clause 5, wherein the second length of each of the plurality of second UBMs is less than a first width of each of the plurality of first UBMs.

7. The die of clause 5 or 6, wherein the first axis of at least one second UBM of the plurality of second UBMs intersects a center area of the die in the core area.

8. The die of any of clauses 5-7, wherein:
the plurality of UBMs further comprises a plurality of third, symmetrical-shaped UBMs;
the plurality of UBMs further comprises at least one row of UBMs; and
each row of the at least one row of UBMs comprises the plurality of third, symmetrical-shaped UBMs each disposed between two adjacent second, oblong-shaped UBMs of the plurality of second, oblong-shaped UBMs.

9. The die of any of clauses 5-8, wherein:
the plurality of UBMs further comprises a plurality of third, symmetrical-shaped UBMs; and
each third, symmetrical-shaped UBM of the plurality of third, symmetrical-shaped UBMs is disposed between two adjacent second, oblong-shaped UBMs of the plurality of second, oblong-shaped UBMs.

10. The die of any of clauses 5-9, wherein:
the plurality of UBMs further comprises a plurality of third, symmetrical-shaped UBMs each having a third axis in a third direction and a fourth axis in a fourth direction orthogonal to the third direction;
the plurality of UBMs further comprises at least one row of UBMs;
each row of the at least one row of UBMs comprises the plurality of third, symmetrical-shaped UBMs each disposed between two adjacent second, oblong-shaped UBMs of the plurality of second, oblong-shaped UBMs; and
the first axis of the two adjacent second, oblong-shaped UBMs is non-perpendicular to the third axis and the fourth axis.

11. The die of any of clauses 1-10 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

12. A method of fabricating an integrated circuit (IC) package, comprising:
providing a semiconductor die (die) comprising:
   a core area; and
   a periphery area surrounding the core area; and
forming a plurality of under bump metallizations (UBMs) in the die, comprising:
   forming a plurality of first UBMs each having a first size and a first pitch; and
   forming a plurality of second UBMs each having a second size smaller than the first size, and each having a second pitch less than the first pitch;
   wherein:
      forming the plurality of second UBMs further comprises forming a first subset of the plurality of second UBMs in the core area of the die.

13. The method of clause 12, wherein forming the plurality of second UBMs further comprises forming a second subset of the plurality of second UBMs in the periphery area of the die.

14. The method of clause 12 or 13, wherein forming the plurality of first UBMs further comprises forming a first subset of the plurality of first UBMs is in the periphery area of the die.

15. The method of clause 14, wherein forming the plurality of first UBMs further comprises forming a second subset of the plurality of first UBMs in the core area of the die.

16. The method of any of clauses 12-15, wherein the forming the plurality of second UBMs comprises forming a plurality of second, oblong-shaped UBMs each having the second size smaller than the first size, and each having the second pitch less than the first pitch;
wherein the plurality of second, oblong-shaped UBMs each have a first length along a first axis and a second length less than the first length along a second axis orthogonal to the first axis.

17. The method of clause 16, wherein forming the plurality of second, oblong-shaped UBMs further comprises forming the plurality of second, oblong-shaped UBMs to each have the second length smaller than a first width of each of the plurality of first UBMs.

18. The method of any of clauses 12-17, further comprising:
forming each first interconnect bump of a plurality of first interconnect bumps coupled to an UBM of the plurality of first UBMs;
forming each second interconnect bump of a plurality of second interconnect bumps coupled to a second UBM of the plurality of second UBMs;
providing a package substrate comprising a first metallization layer comprising a plurality of first metal interconnects and a plurality of second metal interconnects;
coupling each first interconnect bump of the plurality of first interconnect bumps to a first metal interconnect of the plurality of first metal interconnects; and
coupling each second interconnect bump of the plurality of second interconnect bumps to a second metal interconnect of the plurality of first metal interconnects.

19. The method of clause 18, wherein:
the package substrate further comprises:
   a solder resist layer between the first metallization layer and the die, the solder resist layer comprising:
      a plurality of first openings each adjacent to and at least partially exposing a first metal interconnect of the plurality of first metal interconnects; and
   a plurality of metal traces disposed on a first surface of the first metallization layer and the die, each metal trace of the plurality of metal traces coupled to a second metal interconnect of the plurality of second metal interconnects;
wherein:
   coupling each first interconnect bump comprises disposing each first interconnect bump of the plurality of first interconnect bumps through a first opening of the plurality of first openings and coupled to a first metal interconnect of the plurality of first metal interconnects; and
   coupling each second interconnect bump comprises coupling each second interconnect bump of the plurality of second interconnect bumps to a metal trace of the plurality of metal traces.

20. The method of any of clauses 12-19, comprising forming the plurality of second UBMs each having the second size less than or equal to one hundred ten micrometers (110 μm) and smaller than the first size, and each having the second pitch less or equal to seventy (70) μm and less than the first pitch.

21. An integrated circuit (IC) package, comprising:
a package substrate, comprising:
   a first metallization layer comprising a plurality of first metal interconnects and a plurality of second metal interconnects; and
a semiconductor die (die), comprising:
   a core area;
   a periphery area surrounding the core area;
   a plurality of under bump metallizations (UBMs), comprising:
      a plurality of first UBMs each having a first size and a first pitch; and
      a plurality of second UBMs each having a second size smaller than the first size, and each having a second pitch less than the first pitch, wherein a first subset of the plurality of second UBMs is in the core area;
   wherein:
      each first UBM of the plurality of first UBMs is coupled to a first metal interconnect of the plurality of first metal interconnects; and
      each second UBM of the plurality of second UBMs is coupled to a second metal interconnect of the plurality of second metal interconnects.

22. IC package of clause 21, wherein a second subset of the plurality of second UBMs is in the periphery area of the die.

23. The IC package of clause 21 or 22, wherein a first subset of the plurality of first UBMs is in the periphery area of the die.

24. The IC package of clause 23, wherein a second subset of the plurality of first UBMs is in the core area of the die.

25. The IC package of any of clauses 21-24, wherein the plurality of second UBMs comprises a plurality of second, oblong-shaped UBMs each having a first length along a first axis and a second length less than the first length along a second axis orthogonal to the first axis.

26. The IC package of any of clauses 21-25, wherein the die further comprises:
a plurality of first interconnect bumps each coupled to a first UBM of the plurality of first UBMs and each coupled to the first metal interconnect of the plurality of first metal interconnects; and
a plurality of second interconnect bumps each coupled to a second UBM of the plurality of second UBMs and each coupled to the second metal interconnect of the plurality of second metal interconnects.

27. The IC package of clause 26, wherein:
the package substrate further comprises:
   a solder resist layer between the first metallization layer and the die, the solder resist layer comprising:
      a plurality of first openings each adjacent to and at least partially exposing a first metal interconnect of the plurality of first metal interconnects; and
   a plurality of metal traces disposed on a first surface of the solder resist layer between the first metallization layer and the die, each metal trace of the plurality of metal traces coupled to a second metal interconnect of the plurality of second metal interconnects;
each first interconnect bump of the plurality of first interconnect bumps is disposed through a first opening of the plurality of first openings and coupled to a first metal interconnect of the plurality of first metal interconnects; and
each second interconnect bump of the plurality of second interconnect bumps is coupled to a metal trace of the plurality of metal traces.

28. The IC package of clause 27, wherein:
the second size is less than or equal to one hundred ten (110) micrometers (μm); and
the second pitch is less than or equal to seventy (70) μm.

29. The IC package of clause 27 or 28, wherein the first pitch is equal to a third pitch of the plurality of first openings in the solder resist layer.

30. The IC package of any of clauses 21-29 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

What is claimed is:

1. A semiconductor die (die), comprising:
a core area;
a periphery area surrounding the core area; and
a plurality of under bump metallizations (UBMs), comprising:
a plurality of first UBMs each having a first size and a first pitch; and
a plurality of second UBMs each having a second size smaller than the first size, and each having a second pitch less than the first pitch;
wherein:
a first subset of the plurality of second UBMs is in the core area.

2. The die of claim 1, wherein a second subset of the plurality of second UBMs, different from the first subset of the plurality of second UBMs, is in the periphery area.

3. The die of claim 1, wherein a first subset of the plurality of first UBMs is in the periphery area.

4. The die of claim 3, wherein a second subset of the plurality of first UBMs is in the core area.

5. The die of claim 1, wherein the plurality of second UBMs comprises a plurality of second, oblong-shaped UBMs that each have a first length along a first axis and a second length less than the first length along a second axis orthogonal to the first axis.

6. The die of claim 5, wherein the second length of each of the plurality of second UBMs is less than a first width of each of the plurality of first UBMs.

7. The die of claim 5, wherein the first axis of at least one second UBM of the plurality of second UBMs intersects a center area of the die in the core area.

8. The die of claim 5, wherein:
the plurality of UBMs further comprises a plurality of third, symmetrical-shaped UBMs;
the plurality of UBMs further comprises at least one row of UBMs; and
each row of the at least one row of UBMs comprises the plurality of third, symmetrical-shaped UBMs each disposed between two adjacent second, oblong-shaped UBMs of the plurality of second, oblong-shaped UBMs.

9. The die of claim 5, wherein:
the plurality of UBMs further comprises a plurality of third, symmetrical-shaped UBMs; and
each third, symmetrical-shaped UBM of the plurality of third, symmetrical-shaped UBMs is disposed between two adjacent second, oblong-shaped UBMs of the plurality of second, oblong-shaped UBMs.

10. The die of claim 5, wherein:
the plurality of UBMs further comprises a plurality of third, symmetrical-shaped UBMs each having a third axis in a third direction and a fourth axis in a fourth direction orthogonal to the third direction;
the plurality of UBMs further comprises at least one row of UBMs;
each row of the at least one row of UBMs comprises the plurality of third, symmetrical-shaped UBMs each disposed between two adjacent second, oblong-shaped UBMs of the plurality of second, oblong-shaped UBMs; and
the first axis of the two adjacent second, oblong-shaped UBMs is non-perpendicular to the third axis and the fourth axis.

11. The die of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

12. A method of fabricating an integrated circuit (IC) package, comprising:
providing a semiconductor die (die) comprising:
a core area; and
a periphery area surrounding the core area; and
forming a plurality of under bump metallizations (UBMs) in the die, comprising:
forming a plurality of first UBMs each having a first size and a first pitch; and
forming a plurality of second UBMs each having a second size smaller than the first size, and each having a second pitch less than the first pitch;
wherein:
forming the plurality of second UBMs further comprises forming a first subset of the plurality of second UBMs in the core area of the die.

13. The method of claim 12, wherein forming the plurality of second UBMs further comprises forming a second subset of the plurality of second UBMs in the periphery area of the die.

14. The method of claim 12, wherein forming the plurality of first UBMs further comprises forming a first subset of the plurality of first UBMs is in the periphery area of the die.

15. The method of claim 14, wherein forming the plurality of first UBMs further comprises forming a second subset of the plurality of first UBMs in the core area of the die.

16. The method of claim 12, wherein the forming the plurality of second UBMs comprises forming a plurality of second, oblong-shaped UBMs each having the second size smaller than the first size, and each having the second pitch less than the first pitch;
wherein the plurality of second, oblong-shaped UBMs each have a first length along a first axis and a second length less than the first length along a second axis orthogonal to the first axis.

17. The method of claim 16, wherein forming the plurality of second, oblong-shaped UBMs further comprises forming the plurality of second, oblong-shaped UBMs to each have the second length smaller than a first width of each of the plurality of first UBMs.

18. The method of claim 12, further comprising:
forming each first interconnect bump of a plurality of first interconnect bumps coupled to an UBM of the plurality of first UBMs;
forming each second interconnect bump of a plurality of second interconnect bumps coupled to a second UBM of the plurality of second UBMs;
providing a package substrate comprising a first metallization layer comprising a plurality of first metal interconnects and a plurality of second metal interconnects;
coupling each first interconnect bump of the plurality of first interconnect bumps to a first metal interconnect of the plurality of first metal interconnects; and
coupling each second interconnect bump of the plurality of second interconnect bumps to a second metal interconnect of the plurality of first metal interconnects.

19. The method of claim 18, wherein:
the package substrate further comprises:
a solder resist layer between the first metallization layer and the die, the solder resist layer comprising:
a plurality of first openings each adjacent to and at least partially exposing a first metal interconnect of the plurality of first metal interconnects; and
a plurality of metal traces disposed on a first surface of the first metallization layer and the die, each metal trace of the plurality of metal traces coupled to a second metal interconnect of the plurality of second metal interconnects;
wherein:
coupling each first interconnect bump comprises disposing each first interconnect bump of the plurality of first interconnect bumps through a first opening of the plurality of first openings and coupled to a first metal interconnect of the plurality of first metal interconnects; and
coupling each second interconnect bump comprises coupling each second interconnect bump of the plurality of second interconnect bumps to a metal trace of the plurality of metal traces.

20. The method of claim 12, comprising forming the plurality of second UBMs each having the second size less than or equal to one hundred ten micrometers (110 μm) and smaller than the first size, and each having the second pitch less or equal to seventy (70) μm and less than the first pitch.

21. An integrated circuit (IC) package, comprising:
a package substrate, comprising:
a first metallization layer comprising a plurality of first metal interconnects and a plurality of second metal interconnects; and
a semiconductor die (die), comprising:
a core area;
a periphery area surrounding the core area;
a plurality of under bump metallizations (UBMs), comprising:
a plurality of first UBMs each having a first size and a first pitch; and
a plurality of second UBMs each having a second size smaller than the first size, and each having a second pitch less than the first pitch, wherein a first subset of the plurality of second UBMs is in the core area;
wherein:
each first UBM of the plurality of first UBMs is coupled to a first metal interconnect of the plurality of first metal interconnects; and
each second UBM of the plurality of second UBMs is coupled to a second metal interconnect of the plurality of second metal interconnects.

22. IC package of claim 21, wherein a second subset of the plurality of second UBMs is in the periphery area of the die.

23. The IC package of claim 21, wherein a first subset of the plurality of first UBMs is in the periphery area of the die.

24. The IC package of claim 23, wherein a second subset of the plurality of first UBMs is in the core area of the die.

25. The IC package of claim 21, wherein the plurality of second UBMs comprises a plurality of second, oblong-shaped UBMs each having a first length along a first axis and a second length less than the first length along a second axis orthogonal to the first axis.

26. The IC package of claim 21, wherein the die further comprises:
a plurality of first interconnect bumps each coupled to a first UBM of the plurality of first UBMs and each coupled to the first metal interconnect of the plurality of first metal interconnects; and
a plurality of second interconnect bumps each coupled to a second UBM of the plurality of second UBMs and each coupled to the second metal interconnect of the plurality of second metal interconnects.

27. The IC package of claim 26, wherein:
the package substrate further comprises:
a solder resist layer between the first metallization layer and the die, the solder resist layer comprising:
a plurality of first openings each adjacent to and at least partially exposing a first metal interconnect of the plurality of first metal interconnects; and
a plurality of metal traces disposed on a first surface of the solder resist layer between the first metallization layer and the die, each metal trace of the plurality of metal traces coupled to a second metal interconnect of the plurality of second metal interconnects;
each first interconnect bump of the plurality of first interconnect bumps is disposed through a first opening of the plurality of first openings and coupled to a first metal interconnect of the plurality of first metal interconnects; and
each second interconnect bump of the plurality of second interconnect bumps is coupled to a metal trace of the plurality of metal traces.

28. The IC package of claim 27, wherein:
the second size is less than or equal to one hundred ten (110) micrometers (μm); and
the second pitch is less than or equal to seventy (70) μm.

29. The IC package of claim 27, wherein the first pitch is equal to a third pitch of the plurality of first openings in the solder resist layer.

30. The IC package of claim 21 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
